(19) United States
(12) Patent Application Publication
(10) Pub. No.: US 2026/0023100 A1
(43) Pub. Date: Jan. 22, 2026

(54) CURRENT SENSOR MODULE

(71) Applicant: Asahi Kasei Microdevices Corporation, Tokyo (JP)

(72) Inventor: Kenji SUZUKI, Tokyo (JP)

(21) Appl. No.: 19/263,502

(22) Filed: Jul. 9, 2025

(30) Foreign Application Priority Data
Jul. 16, 2024 (JP) 2024-113400
May 30, 2025 (JP) 2025-090685

(51) Int. Cl. G01R 15/20; G01R 19/00

(52) U.S. Cl. CPC G01R 15/202; G01R 19/0092

(57) ABSTRACT

A sealing section seals a part of a first current conductor, a first magnetoelectric conversion element, a part of a second current conductor, a second magnetoelectric conversion element, a signal processing IC, and a part of a signal conductor. The part of the first current conductor is exposed from a first surface of the sealing section, the part of the second current conductor is exposed from a second surface facing the first surface of the sealing section in a first direction, and the part of the signal conductor is exposed from a third surface of the sealing section. The sealing section includes a first groove formed along the first surface or the third surface.

The contents of the following patent application(s) are incorporated herein by reference:
NO. 2024-113400 filed in JP on Jul. 16, 2024
NO. 2025-090685 filed in JP on May 30, 2025.

### BACKGROUND

### 1. Technical Field

The present invention relates to a current sensor module.

### 2. Related Art

Patent document 1 discloses a current sensor which can measure currents to be measured for two channels.

### RELATED ART DOCUMENTS

### Patent Document

Patent Document 1: International Publication No. 2015/033541

### BRIEF DESCRIPTION OF THE DRAWINGS

FIG. 1A is a schematic plan view of a current sensor and a substrate according to a first embodiment as viewed from a top surface side (positive z axis direction).

FIG. 1B is a side view of the current sensor and the substrate illustrated in FIG. 1A as viewed from a negative x axis direction.

FIG. 1C is a side view of the current sensor and the substrate illustrated in FIG. 1A as viewed from a negative y axis direction.

FIG. 2 is a diagram for describing a positional relationship between a magnetoelectric conversion element and a current conductor in the first embodiment.

FIG. 3 is a diagram for describing a positional relationship between the magnetoelectric conversion element and the current conductor according to a modified example of the first embodiment.

FIG. 4A is a schematic plan view of the current sensor and the substrate according to a second embodiment as viewed from the top surface side (positive z axis direction).

FIG. 4B is a side view of the current sensor and the substrate illustrated in FIG. 4A as viewed from the negative x axis direction.

FIG. 4C is a side view of the current sensor and the substrate illustrated in FIG. 4A as viewed from a positive y axis direction.

FIG. 5A is a schematic plan view of the current sensor according to a third embodiment as viewed from the top surface side (positive z axis direction).

FIG. 5B is a side view of the current sensor and the substrate illustrated in FIG. 5A as viewed from the negative x axis direction.

FIG. 5C is a side view of the current sensor and the substrate illustrated in FIG. 5A as viewed from the negative y axis direction.

FIG. 6 is a side view of the current sensor and the substrate of the third embodiment in a case of an insert mounting type as viewed from the negative x axis direction.

FIG. 7A is a schematic plan view of the current sensor and the substrate according to a fourth embodiment as viewed from the top surface side (positive z axis direction).

FIG. 7B is a side view of the current sensor and the substrate illustrated in FIG. 7A as viewed from the negative x axis direction.

FIG. 7C is a side view of the current sensor and the substrate illustrated in FIG. 7A as viewed from the negative y axis direction.

FIG. 8A is a schematic plan view of the current sensor and the substrate according to a fifth embodiment as viewed from the top surface side (positive z axis direction).

FIG. 8B is a side view of the current sensor and the substrate illustrated in FIG. 8A as viewed from the negative x axis direction.

FIG. 8C is a side view of the current sensor and the substrate illustrated in FIG. 8A as viewed from the negative y axis direction.

FIG. 9A is a diagram for describing another example of the positional relationship between the magnetoelectric conversion element and the current conductor.

FIG. 9B is a diagram for describing another example of the positional relationship between the magnetoelectric conversion element and the current conductor.

FIG. 10 is a schematic plan view of the current sensor mounted to a substrate having a slit as viewed from the top surface side (positive z axis direction).

FIG. 11 is a schematic plan view of the current sensor mounted to the substrate having the slit as viewed from the top surface side (positive z axis direction).

FIG. 12A is a schematic plan view of the current sensor according to a sixth embodiment as viewed from the top surface side (positive z axis direction).

FIG. 12B is a side view of the current sensor illustrated in FIG. 12A as viewed from the negative x axis direction.

FIG. 12C is a side view of the current sensor illustrated in FIG. 12A as viewed from the negative y axis direction.

FIG. 13A is a schematic plan view of the current sensor according to a seventh embodiment as viewed from the top surface side (positive z axis direction).

FIG. 13B is a side view of the current sensor illustrated in FIG. 13A as viewed from the negative x axis direction.

FIG. 13C is a side view of the current sensor illustrated in FIG. 13A as viewed from the negative y axis direction.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to the solution of the invention.

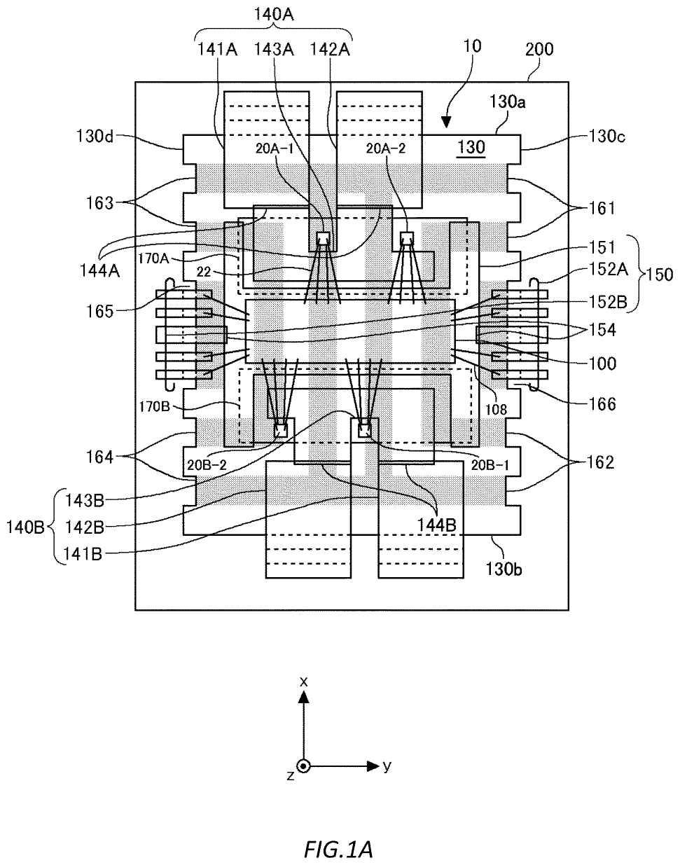

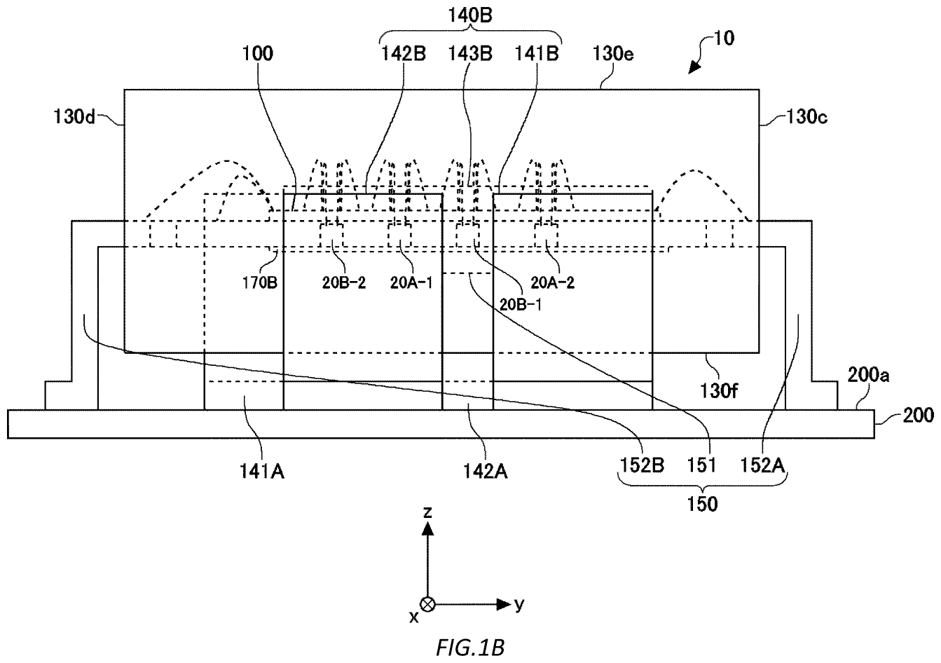

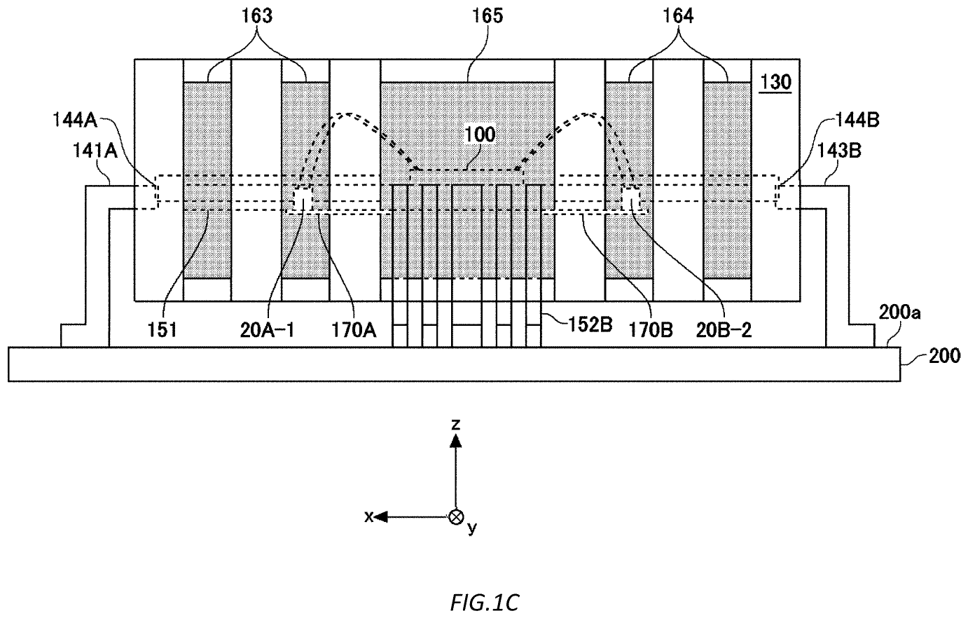

FIG. 1A is a schematic plan view of a current sensor 10 and a substrate 200 as viewed from a top surface side (positive z axis direction) according to a first embodiment. FIG. 1B is a side view of the current sensor 10 and the substrate 200 illustrated in FIG. 1A as viewed from a negative x axis direction. FIG. 1C is a side view of the current sensor 10 and the substrate 200 illustrated in FIG. 1A as viewed from a negative y axis direction. With regard to coordinates, in FIG. 1A, an orientation that is parallel and from bottom to top in relation to a paper surface is defined as an x axis direction, an orientation that is parallel and from left to right in relation to the paper surface is defined as a y axis direction, and an orientation that is perpendicular and from back to front in relation to the paper surface is defined as a z axis direction. Any one of axes of an x axis, a y axis, and a z axis are orthogonal to the other axes. The x axis is an example of a first direction, the y axis is an example of a second direction, and the z axis is an example of a third direction.

The current sensor 10 includes a signal processing IC 100, magnetoelectric conversion elements 20A-1, 20A-2, 20B-1, and 20B-2, current conductors 140A and 140B on a primary side, a signal conductor 150 on a secondary side, a support board 170A, a support board 170B, and a sealing section 130. The current sensor 10 includes the two current conductors 140A and 140B to measure currents to be measured for two channels. The magnetoelectric conversion elements 20A-1, 20A-2, 20B-1, and 20B-2 may be collectively referred to as a magnetoelectric conversion element 20. The magnetoelectric conversion element 20A-1 is an example of a first magnetoelectric conversion element. The magnetoelectric conversion element 20A-2 is an example of a third magnetoelectric conversion element. The magnetoelectric conversion element 20B-1 is an example of a second magnetoelectric conversion element. The magnetoelectric conversion element 20B-2 is an example of a fourth magnetoelectric conversion element. The current conductor 140A is an example of a first current conductor. The current conductor 140B is an example of a second current conductor.

The sealing section 130 seals the magnetoelectric conversion element 20, a part of the current conductor 140A, a part of the current conductor 140B, the signal processing IC 100, the support board 170A, the support board 170B, and the signal conductor 150 with a resin material. The resin material may be, for example, an epoxy thermosetting resin added with silica or a thermoplastic resin such as a liquid crystal polymer. The sealing section 130 may be formed by compression molding, transfer molding, or the like using a mold.

The current conductor 140A and the current conductor 140B are conductors through which different currents to be measured under measurement respectively flow. The current conductor 140A and the current conductor 140B are electrically connected to, for example, of three-phase electric lines of a three-phase AC circuit such as a three-phase motor, any two phases (for example, a U phase and a V phase) electric lines through which the current to be measured under measurement flows.

The current conductor 140A and the current conductor 140B may have a same shape in plan view. The current conductor 140A and the current conductor 140B may be configured by a single lead frame. In plan view, the current conductor 140A extends in the x axis direction and also extends in the y axis direction together with a conductor portion 141A and a conductor portion 142A which are apart in the y axis direction, and includes a conductor portion 143A which couples the conductor portion 141A and the conductor portion 142A. The conductor portion 141A and the conductor portion 142A and the conductor portion 143A may form a U shape in plan view. One end of the conductor portion 141A and one end of the conductor portion 142A are exposed from a surface 130a of the sealing section 130. The conductor portion 143A couples another end of the conductor portion 141A and another end of the conductor portion 142A.

The conductor portion 141A and the conductor portion 142A may have a stepped section 144A so as to leave the signal conductor 150 in the z axis direction such that the current conductor 140A and the signal conductor 150 are not in contact in the z axis direction (thickness direction). The conductor portion 141A is an example of a first conductor portion, the conductor portion 142A is an example of a second conductor portion, and the conductor portion 143A is an example of a third conductor portion.

The current conductor 140B extends in the x axis direction in plan view and also extends in the y axis direction together with a conductor portion 141B and a conductor portion 142B which are apart in the y axis direction, and includes a conductor portion 143B which couples the conductor portion 141B and the conductor portion 142B. The conductor portion 141B and the conductor portion 142B and the conductor portion 143B may form a U shape in plan view. One end of the conductor portion 141B and one end of the conductor portion 142B are exposed from a surface 130b opposite to the surface 130a of the sealing section 130. The conductor portion 143B couples another end of the conductor portion 141B and another end of the conductor portion 142B.

The conductor portion 141B and the conductor portion 142B may have a stepped section 144B so as to leave the signal conductor 150 in the z axis direction such that the current conductor 140B and the signal conductor 150 are not in contact in the z axis direction (thickness direction). The conductor portion 141B is an example of a fourth conductor portion, the conductor portion 142B is an example of a fifth conductor portion, and the conductor portion 143B is an example of a sixth conductor portion.

The signal conductor 150 may be configured by another lead frame different from the lead frame configuring the current conductor 140A and the current conductor 140B. The signal conductor 150 includes a support section 151, a terminal section 152A, and a terminal section 152B. The terminal section 152A and the terminal section 152B are electrically connected to the signal processing IC 100 via a wire 108. A signal output from the signal processing IC 100 is output to the outside via the signal conductor 150. A part of the terminal section 152A is exposed from a surface 130c that is different from the surface 130a and the surface 130b which are opposite in the x axis direction of the sealing section 130. The surface 130c is adjacent with the surface 130a and the surface 130b along the x axis direction. A part of the terminal section 152B is exposed from a surface 130d which are opposite to the surface 130c in the y axis direction.

The support section 151 is sealed in the sealing section 130 and supports the signal processing IC 100, the support board 170A, and the support board 170B. The terminal section 152A and the terminal section 152B have a plurality of terminals, and a part of the plurality of terminals is integrally configured with the support section 151. At least a part of each of the plurality of terminals is exposed from the surface 130c of the sealing section 130. The support section 151 may have a stepped section 154 in a connection portion between the terminal section 152A and the terminal section 152B so as to leave the current conductor 140A and the current conductor 140B in the z axis direction such that the current conductor 140A and the current conductor 140B and the signal conductor 150 are not in contact in the z axis direction (thickness direction).

The current conductor 140A, the current conductor 140B, and the signal conductor 150 may be formed of a conductive material principally made of copper. The support section 151 may be configured by a metal plate separate from the terminal section 152A and the terminal section 152B or a plate made of a semiconductor, or may be configured by being combined with an insulating member such as a die attach film.

The magnetoelectric conversion element 20A-1 and the magnetoelectric conversion element 20A-2 are arranged on the support board 170A made of an insulating material such as a polyimide tape. The magnetoelectric conversion element 20B-1 and the magnetoelectric conversion element 20B-2 are arranged on the support board 170B made of an insulating material such as a polyimide tape. The support board 170A and the support board 170B are supported to the support section 151.

In FIG. 1A, a portion of the current conductor 140A, a portion of the current conductor 140B, and a portion of the signal conductor 150 are at a same height in the z axis direction, and the magnetoelectric conversion element 20 is supported by the support board 170A and the support board 170B. On the other hand, the current conductor 140A and the current conductor 140B and the signal conductor 150 may be at different heights in the z axis direction. In this case, the support board 170A and the support board 170B are not included, and the magnetoelectric conversion element 20 may be supported to the support section 151.

The magnetoelectric conversion element 20 is electrically connected to the signal processing IC 100 via a wire 22. The wire 22 electrically connects the magnetoelectric conversion element 20 and the signal processing IC 100 across a part of the current conductor 140A or the current conductor 140B. The wire 22 and the wire 108 may be formed of a conductor material, main components of which are Au, Ag, Cu, or Al.

The magnetoelectric conversion element 20 may include a substrate made of a compound semiconductor or silicon and a magnetoelectric conversion section provided on the substrate. The magnetoelectric conversion element 20 has a sensitivity axis in the z axis direction. Since a magnetic field in the z axis direction is detected, in the first embodiment, for example, a Hall element which detects a vertical magnetic field in the thickness direction of the current conductor 140A or the current conductor 140B is appropriate as the magnetoelectric conversion element 20.

The signal processing IC 100 is a large scale integration circuit (LSI). The signal processing IC 100 is a monolithic IC. More specifically, the signal processing IC 100 is a signal processing circuit composed of a Si monolithic semiconductor formed on a Si substrate. The signal processing circuit processes an output signal that depends on an intensity of a magnetic field output from the magnetoelectric conversion element 20.

The signal processing circuit cancels, based on a difference between an output signal of the magnetoelectric conversion element 20A-1 and an output signal of the magnetoelectric conversion element 20A-2, noise components which are caused by a common external magnetic field and included in the output signal of the magnetoelectric conversion element 20A-1 and the output signal of the magnetoelectric conversion element 20A-2, amplifies the output signal of the magnetoelectric conversion element 20A-1 and the output signal of the magnetoelectric conversion element 20A-2 which are obtained by reducing the noise components, calculates a current value Ia of the current to be measured which flows through the current conductor 140A based on the amplified output signals, and outputs an output signal indicating the current value Ia. The signal processing circuit may perform an offset adjustment after cancellation of noise components caused by an external disturbance magnetic field. The signal processing circuit may perform a compensation by a temperature characteristic when the current value Ia is calculated based on the amplified output signal. That is, the signal processing circuit may cancel the noise components caused the external magnetic field commonly applied to the magnetoelectric conversion element 20A-1 and the magnetoelectric conversion element 20A-2, extracts only output components based on the current which flows through the current conductor 140A, and output the output signal after the offset adjustment, the amplification of the output signal, and the compensation by the temperature characteristic are performed.

In addition, the signal processing circuit cancels, based on a difference between an output signal of the magnetoelectric conversion element 20B-1 and an output signal of the magnetoelectric conversion element 20B-2, noise components which are caused by a common external magnetic field and included in the output signal of the magnetoelectric conversion element 20B-1 and the output signal of the magnetoelectric conversion element 20B-2, amplifies the output signal of the magnetoelectric conversion element 20B-1 and the output signal of the magnetoelectric conversion element 20B-2 which are obtained by reducing the noise components, calculates a current value Ib of the current to be measured which flows through the current conductor 140B based on the amplified output signals, and outputs an output signal indicating the current value Ib. Similarly, the signal processing circuit may cancel the noise components caused the external magnetic field commonly applied to the magnetoelectric conversion element 20B-1 and the magnetoelectric conversion element 20B-2, extracts only output components based on the current which flows through the current conductor 140B, and output the output signal after the offset adjustment, the amplification of the output signal, and the compensation by the temperature characteristic are performed.

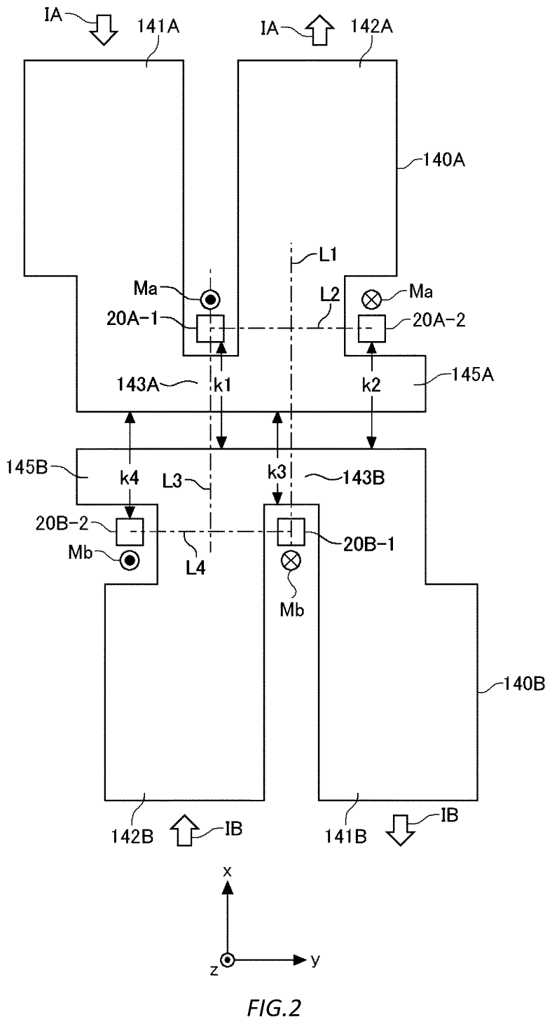

FIG. 2 is a diagram for describing a positional relationship between the magnetoelectric conversion element 20 and the current conductor 140A and the current conductor 140B in the first embodiment. In FIG. 2, an arrow IA indicates a direction of the current to be measured which flows through the current conductor 140A, and an arrow IB indicates a direction of the current to be measured which flows through the current conductor 140B. Marks indicated by a reference sign Ma and a reference sign Mb indicate magnetic flux directions in regions where the marks are located.

The magnetoelectric conversion element 20A-1 and the magnetoelectric conversion element 20A-2 are arranged in a region surrounded by the current conductor 140A in plan view. The magnetoelectric conversion element 20A-1 is arranged in a region surrounded by the conductor portion 141A, the conductor portion 143A, and the conductor portion 142A. The magnetoelectric conversion element 20A-2 is arranged facing the magnetoelectric conversion element 20A-1 across the conductor portion 142A in plan view. The magnetoelectric conversion element 20A-2 is arranged in a region surrounded by the conductor portion 142A, the conductor portion 143A, and an extended portion 145A which elongates in the y axis direction and which is included in the conductor portion 143A. The magnetoelectric conversion element 20A-1 and the magnetoelectric conversion element 20A-2 are arranged in a row along the y axis direction.

The magnetoelectric conversion element 20B-1 and the magnetoelectric conversion element 20B-2 are arranged in a region surrounded by the current conductor 140B in plan view. The magnetoelectric conversion element 20B-1 is arranged in a region surrounded by the conductor portion 141B, the conductor portion 143B, and the conductor portion 142B. The magnetoelectric conversion element 20B-2 is arranged facing the magnetoelectric conversion element 20B-1 across the conductor portion 142B in plan view. The magnetoelectric conversion element 20B-2 is arranged in a region surrounded by the conductor portion 142B, the conductor portion 143B, and an extended portion 145B which elongates in the y axis direction and which is included in the conductor portion 143B. The magnetoelectric conversion element 20B-1 and the magnetoelectric conversion element 20B-2 are arranged in a row along the y axis direction.

The current conductor 140A and the current conductor 140B have a same shape and are in a 180-degree rotated positional relationship in plan view. The shape of the current conductor 140A and the current conductor 140B is not limited to the shape illustrated in FIG. 2, and for example, a shape configured by the conductor portion 141A, the conductor portion 142A, and the conductor portion 143A may be line symmetric with respect to a perpendicular bisector L3, which is set as a symmetric axis, of a line segment L4 connecting the magnetoelectric conversion element 20B-1 and the magnetoelectric conversion element 20B-2 in plan view. A shape configured by the conductor portion 141B, the conductor portion 142B, and the conductor portion 143B may be line symmetric with respect to a perpendicular bisector L1, which is set as a symmetric axis, of a line segment L2 connecting a magnetoelectric conversion element 20A-1 and the magnetoelectric conversion element 20A-2 in plan view.

The magnetoelectric conversion element 20A-1 is positioned on an extending line on which the conductor portion 142B extends in plan view. The magnetoelectric conversion element 20A-2 is positioned on an extending line on which the conductor portion 141B extends in plan view. The magnetoelectric conversion element 20B-1 is positioned on an extending line on which the conductor portion 142A extends in plan view. The magnetoelectric conversion element 20B-2 is positioned on an extending line on which the conductor portion 141A extends in plan view.

Further to explain, the magnetoelectric conversion element 20A-1 is positioned on the perpendicular bisector L3 of the line segment L4 connecting the magnetoelectric conversion element 20B-1 and the magnetoelectric conversion element 20B-2 in plan view. The magnetoelectric conversion element 20B-1 is positioned on the perpendicular bisector L1 of the line segment L2 connecting the magnetoelectric conversion element 20A-1 and the magnetoelectric conversion element 20A-2 in plan view.

In addition, the conductor portion 143B is a current path which extends in a direction along the line segment L2 connecting the magnetoelectric conversion element 20A-1 and the magnetoelectric conversion element 20A-2. In plan view, a distance k1 between the magnetoelectric conversion element 20A-1 and the conductor portion 143B is equal to a distance k2 between the magnetoelectric conversion element 20A-2 and the conductor portion 143B. Thus, due to the current to be measured which flows through the current conductor 140B, the magnetic field caused at the position of the magnetoelectric conversion element 20A-1 becomes equal to the magnetic field caused at the position of the magnetoelectric conversion element 20A-2. As described above, the signal processing circuit calculates a difference between the output signal of the magnetoelectric conversion element 20A-1 and the output signal of the magnetoelectric conversion element 20A-2. Therefore, since the signal processing circuit calculates the difference between the output signal of the magnetoelectric conversion element 20A-1 and the output signal of the magnetoelectric conversion element 20A-2, an influence of the magnetic field caused by the current to be measured which flows through the current conductor 140B can be cancelled. Accordingly, it is possible to suppress an influence of the magnetic field caused by the current to be measured which flows through the current conductor 140B to affect on a measurement result of the current to be measured which flows through the current conductor 140A based on an output result of the output signal of the magnetoelectric conversion element 20A-1 and the output signal of the magnetoelectric conversion element 20A-2.

Similarly, the conductor portion 143A is a current path which extends in a direction along the line segment L4 connecting the magnetoelectric conversion element 20B-1 and the magnetoelectric conversion element 20B-2. In plan view, a distance k3 between the magnetoelectric conversion element 20B-1 and the conductor portion 143A is equal to a distance k4 between the magnetoelectric conversion element 20B-2 and the conductor portion 143A. Thus, due to the current to be measured which flows through the current conductor 140A, the magnetic field caused at the position of the magnetoelectric conversion element 20B-1 becomes equal to the magnetic field caused at the position of the magnetoelectric conversion element 20B-2. Therefore, since the signal processing circuit calculates a difference between the output signal of the magnetoelectric conversion element 20B-1 and the output signal of the magnetoelectric conversion element 20B-2, an influence of the magnetic field caused by the current to be measured which flows through the current conductor 140A can be cancelled. Accordingly, it is possible to suppress an influence of the magnetic field caused by the current to be measured which flows through the current conductor 140A to affect on a measurement result of the current to be measured which flows through the current conductor 140B based on an output result of the output signal of the magnetoelectric conversion element 20B-1 and the output signal of the magnetoelectric conversion element 20B-2.

In the current sensor 10 configured in this manner, an insulation property between the current conductor 140A and the current conductor 140B on the primary side and the signal conductor 150 on the secondary side needs to be ensured. To maintain a high insulation performance, an entirety needs to be covered with an insulating article such as a molded resin to ensure both a spatial distance and a creepage distance. However, when the current conductor 140A and the current conductor 140B on the primary side and the signal conductor 150 on the secondary side are exposed from two sides adjacent to each other instead of opposite two sides of the sealing section 130, if it is attempted to ensure the creepage distance by increasing the distance between the current conductor 140A and the current conductor 140B on the primary side and the signal conductor 150 on the secondary side, a size of the sealing section 130 is increased, which hinders a miniaturization of the current sensor 10.

In view of the above, in the current sensor 10 according to the first embodiment, a groove is provided on a side of the sealing section 130 to ensure the creepage distance.

In FIG. 1A and FIG. 1C, the sealing section 130 has, in the surface 130c, at least one first groove 161 that intersects with a first path on an outer surface which has the shortest distance between an exposed portion of the conductor portion 142A that is an exposed portion of the current conductor 140A and an exposed portion of the terminal section 152A that is an exposed portion of the signal conductor 150 from the surface 130c. The first groove 161 is formed along the surface 130c. Furthermore, the sealing section 130 has, in the surface 130c, at least one second groove 162 that intersects with a second path on an outer surface of the sealing section 130 which has the shortest distance between the conductor portion 141B that is an exposed portion of the current conductor 140B and an exposed portion of the terminal section 152A that is an exposed portion of the signal conductor 150 from the surface 130c. The second groove 162 is formed along the surface 130c.

The first groove 161 extends along the z axis direction in the surface 130c and further reaches a surface 130e that is a top surface and a surface 130f that is a bottom surface to extend in the y axis direction, and thereafter extends along the x axis direction. Similarly, the second groove 162 extends along the z axis direction in the surface 130c and further reaches the surface 130e and the surface 130f to extend in the y axis direction, and thereafter extends along the x axis direction. The first groove 161 and the second groove 162 merge in a portion that extends along the x axis direction of the surface 130e and the surface 130f to form a single groove, and the terminal section 152A is surrounded by the first groove 161 and the second groove 162.

The sealing section 130 has, in the surface 130d, at least one third groove 163 that intersects with a third path on an outer surface which has the shortest distance between an exposed portion of the conductor portion 142A that is the exposed portion of the current conductor 140A and an exposed portion of the terminal section 152B that is an exposed portion of the signal conductor 150 from the surface 130d. The third groove 163 is formed in the surface 130d. Furthermore, the sealing section 130 has, in the surface 130d, at least one fourth groove 164 that intersects with a fourth path on an outer surface of the sealing section 130 which has the shortest distance between the conductor portion 141B that is the exposed portion of the current conductor 140B and the exposed portion of the terminal section 152B that is the exposed portion of the signal conductor 150 from the surface 130d. The fourth groove 164 is formed along the surface 130d.

The third groove 163 extends along the z axis direction in the surface 130d and further reaches the surface 130e and the surface 130f to extend in the y axis direction, and thereafter extends along the x axis direction. Similarly, the fourth groove 164 extends along the z axis direction in the surface 130f and further reaches the surface 130e and the surface 130f to extend in the y axis direction, and thereafter extends along the x axis direction. The third groove 163 and the fourth groove 164 merge in a portion that extends along the x axis direction of the surface 130e and the surface 130f to form a single groove, and the terminal section 152B is surrounded by the third groove 163 and the fourth groove 164.

The sealing section 130 may have a groove 166 which extends in the z axis direction in the exposed portion of the terminal section 152A in a central portion of the surface 130c. Furthermore, the sealing section 130 may have a groove 165 which extends in the z axis direction in the exposed portion of the terminal section 152B in a central portion of the surface 130d.

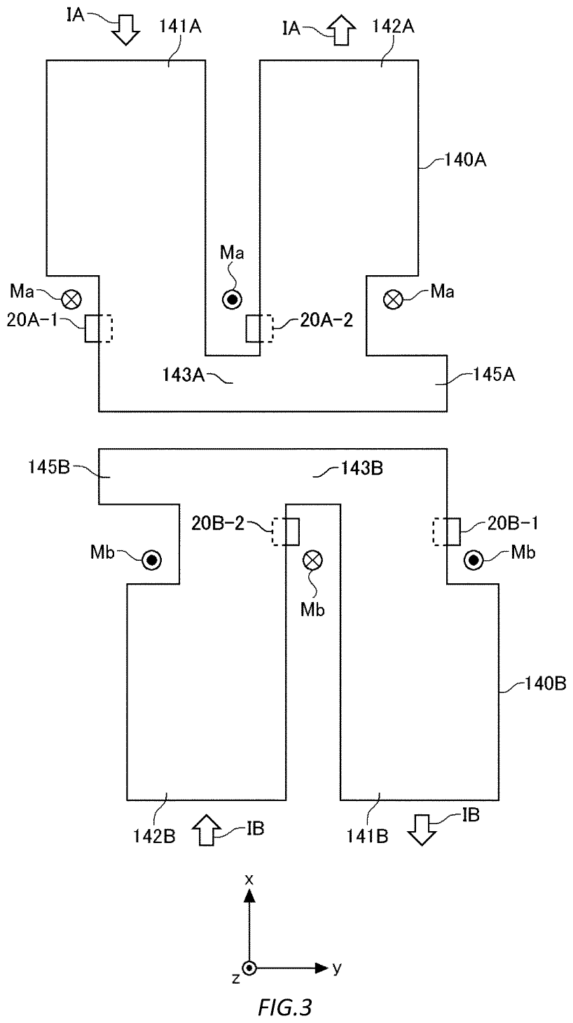

FIG. 3 is a diagram for describing a positional relationship between the magnetoelectric conversion element 20 and the current conductor 140A and the current conductor 140B according to a modified example of the first embodiment. In the example illustrated in FIG. 2, an example has been described in which the magnetoelectric conversion element 20 and the current conductor 140A and the current conductor 140B are arranged in positions that are not overlapped in plan view. However, as illustrated in FIG. 3, the magnetoelectric conversion element 20 and the current conductor 140A or the current conductor 140B may be arranged in positions that may be partially overlapped in plan view. The magnetoelectric conversion element 20A-2 may be arranged facing the conductor portion 141A across a part thereof in plan view. The magnetoelectric conversion element 20B-2 may be arranged facing the conductor portion 141B across a part thereof in plan view. A half of a magnetically sensitive surface of the magnetoelectric conversion element 20 may be overlapped with the current conductor 140A or the current conductor 140B in plan view.

As in a current sensor illustrated in FIG. 3, when the magnetoelectric conversion element 20 is arranged in a position partially overlapped with the current conductor 140A or the current conductor 140B in plan view, with regard to the sensitivity axis of the magnetoelectric conversion element, not only the z axis direction but a magnetic field in any one axis direction at and above the xy plane horizontal to the magnetically sensitive surface may be detected. Accordingly, in the current sensor according to the modified example of the first embodiment illustrated in FIG. 3, the magnetoelectric conversion element 20 may be a Hall element using a Hall effect or may be a magnetoresistance element using a magnetoresistance effect. The magnetoresistance element may be, for example, a semiconductor magnetic resistor element (SMR), an anomalous magnetoresistive element (AMR), a giant magnetoresistive element (GMR), or a tunnel magnetoresistive element (TMR).

As described above, in accordance with the current sensor 10 according to the first embodiment, since the grooves are provided on the sides of the sealing section 130, in the current sensor 10 which includes the two current conductors 140A and 140B and can measure the currents to be measured for two channels, while a miniaturization is achieved, the creepage distance between the current conductor 140A and the current conductor 140B and the signal conductor 150 can be ensured.

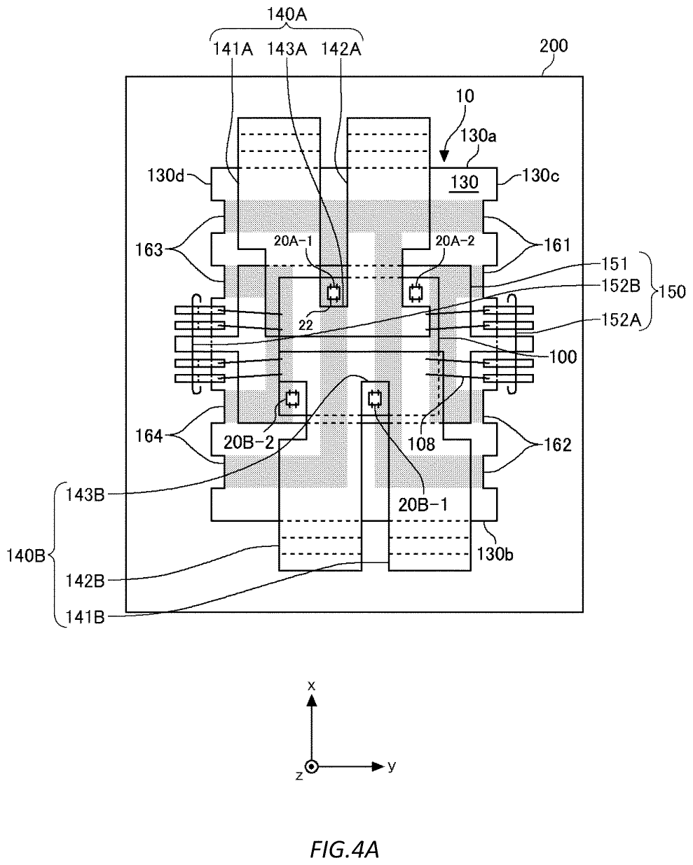

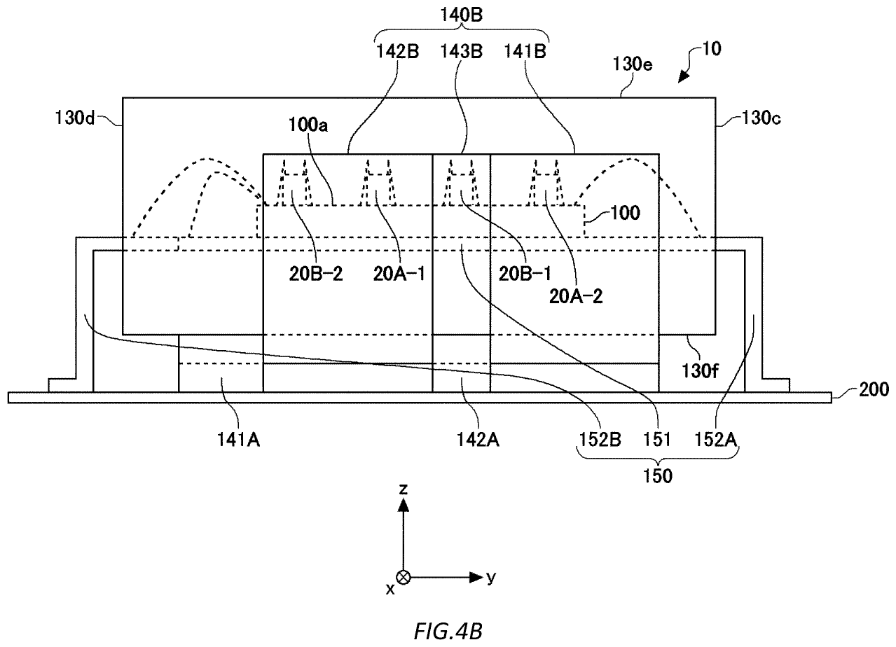

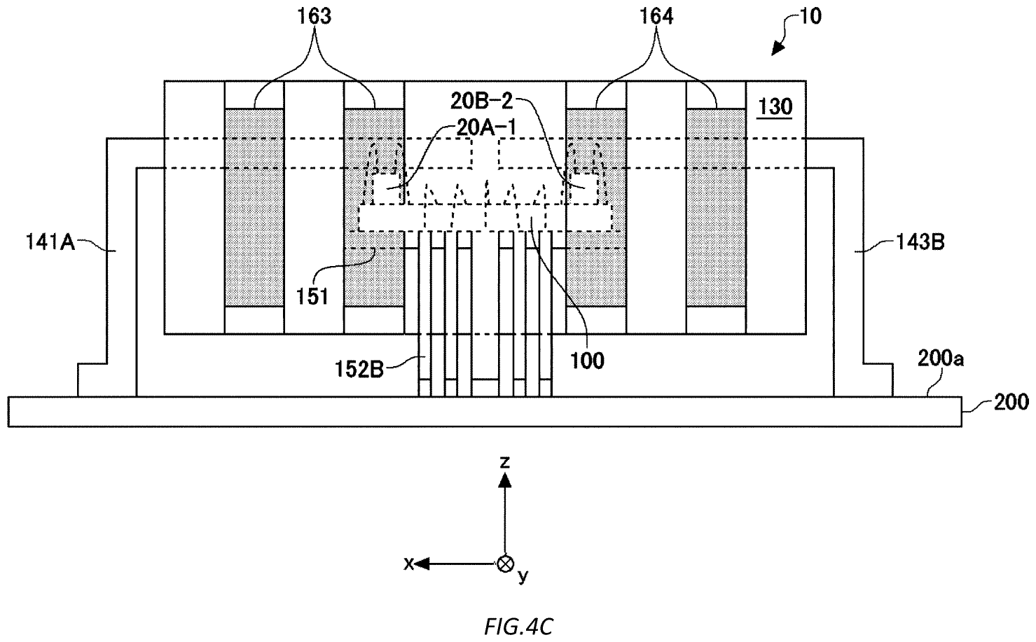

FIG. 4A is a schematic plan view of the current sensor 10 and the substrate 200 as viewed from the top surface side (positive z axis direction) according to a second embodiment. FIG. 4B is a side view of the current sensor 10 and the substrate 200 illustrated in FIG. 4A as viewed from the negative x axis direction. FIG. 4C is a side view of the current sensor 10 and the substrate 200 illustrated in FIG. 4A as viewed from the negative y axis direction. With regard to coordinates, in FIG. 4A, an orientation that is parallel and from bottom to top in relation to the paper surface is defined as an x axis direction, an orientation that is parallel and from left to right in relation to the paper surface is defined as a y axis direction, and an orientation that is perpendicular and from back to front in relation to the paper surface is defined as a z axis direction. Any one of axes of an x axis, a y axis, and a z axis are orthogonal to the other axes.

The current sensor 10 according to the second embodiment is different from the current sensor 10 according to the first embodiment in that the magnetoelectric conversion element 20 is mounted on a surface 100a that is a circuit surface of the signal processing IC. The circuit surface is equivalent to a top surface of a semiconductor package configuring the signal processing IC 100.

Since the magnetoelectric conversion element 20 is mounted on the surface 100a of the signal processing IC 100, the magnetoelectric conversion element 20 and the signal processing IC 100 can be electrically connected by the wire 22 without crossing the current conductors 140A and 140B. Thus, a deformation of the wire 22 hardly occurs, and an optimization of the shape of the wire 22 is relatively easy, so that a deterioration of an electrical characteristics such as responsiveness of the current sensor 10 can be suppressed.

In this manner, since the magnetoelectric conversion element 20 is mounted on the surface 100a of the signal processing IC 100, the wire 22 can be arranged without crossing the current conductors 140A and 140B. Thus, the conductor portion 143A and the conductor portion 143B can be arranged being apart and facing in plan view, and the distance between the current conductor 140A and the current conductor 140B can be shortened. In plan view, the distance between portions where the current conductor 140A and the current conductor 140B mutually face each other, that is, the conductor portion 143A and the conductor portion 143B may be 2 mm or less and 0.1 mm or more. Thus, a width of the sealing section 130 in the x axis direction can be reduced, and it is possible to miniaturize the current sensor 10 which can measure the currents to be measured for two channels. The resin material configuring the sealing section 130 is filled between the conductor portion 143A and the conductor portion 143B. Thus, an insulation property between the conductor portion 143A and the conductor portion 143B can be ensured.

By shortening the distance between the conductor portion 143A and the conductor portion 143B, the miniaturization of the sealing section 130 can be achieved. On the other hand, when the distance between the conductor portion 143A and the conductor portion 143B is shortened, it becomes difficult to ensure a sufficient length of the creepage distance while keeping the distance apart between the current conductor 140A and the current conductor 140B on the primary side and the signal conductor 150 on the secondary side.

In view of the above, in the current sensor 10 according to the second embodiment, similarly as in the current sensor 10 according to the first embodiment, grooves are provided in the outer surface of the sealing section 130, and a sufficient length of the creepage distance is to be ensured.

In FIG. 4A and FIG. 4C, the sealing section 130 has, in the surface 130c, at least one first groove 161 that intersects with the first path on the outer surface which has the shortest distance between the exposed portion of the conductor portion 142A that is the exposed portion of the current conductor 140A and the exposed portion of the terminal section 152A that is the exposed portion of the signal conductor 150 from the surface 130c. Furthermore, the sealing section 130 has, in the surface 130c, at least one second groove 162 that intersects with the second path on the outer surface of the sealing section 130 which has the shortest distance between the conductor portion 141B that is the exposed portion of the current conductor 140B and the exposed portion of the terminal section 152A that is the exposed portion of the signal conductor 150 from the surface 130c.

The first groove 161 extends along the z axis direction in the surface 130c and further reaches the surface 130e that is the top surface and the surface 130f that is the bottom surface to extend in the y axis direction, and thereafter extends along the x axis direction. Similarly, the second groove 162 extends along the z axis direction in the surface 130c and further reaches the surface 130e and the surface 130f to extend in the y axis direction, and thereafter extends along the x axis direction. The first groove 161 and the second groove 162 merge in a portion which extends in the x axis direction of the surface 130e and the surface 130f to form a single groove, and the terminal section 152A is surrounded by the first groove 161 and the second groove 162.

The sealing section 130 has, in the surface 130d, at least one third groove 163 that intersects with the third path on the outer surface which has the shortest distance between the exposed portion of the conductor portion 141A that is the exposed portion of the current conductor 140A and the exposed portion of the terminal section 152B that is the exposed portion of the signal conductor 150 from the surface 130d. Furthermore, the sealing section 130 has, in the surface 130d, at least one fourth groove 164 that intersects with the fourth path on the outer surface of the sealing section 130 which has the shortest distance between the conductor portion 141B that is the exposed portion of the current conductor 140B and the exposed portion of the terminal section 152B that is the exposed portion of the signal conductor 150 from the surface 130d. The third groove 163 extends along the z axis direction in the surface 130d and further reaches the surface 100e and the surface 130f to extend in the y axis direction, and thereafter extends along the x axis direction. Similarly, the fourth groove 164 extends along the z axis direction in the surface 130d and further reaches the surface 100e and the surface 130f to extend in the y axis direction, and thereafter extends along the x axis direction.

The third groove 163 and the fourth groove 164 merge in a portion that extends along the x axis direction of the surface 130e and the surface 130f to form a single groove, and the terminal section 152B is surrounded by the third groove 163 and the fourth groove 164.

As described above, in accordance with the current sensor 10 according to the second embodiment, since the grooves are provided on the sides of the sealing section 130, in the current sensor 10 which includes the two current conductors 140A and 140B and can measure the currents to be measured for two channels, by mounting the magnetoelectric conversion element 20 to the circuit surface of the signal processing IC 100, while the distance between the current conductor 140A and the current conductor 140B is shortened to achieve a further miniaturization as compared with the current sensor 10 according to the first embodiment, the creepage distance between the current conductors 140A and 140B and the signal conductor 150 can be ensured.

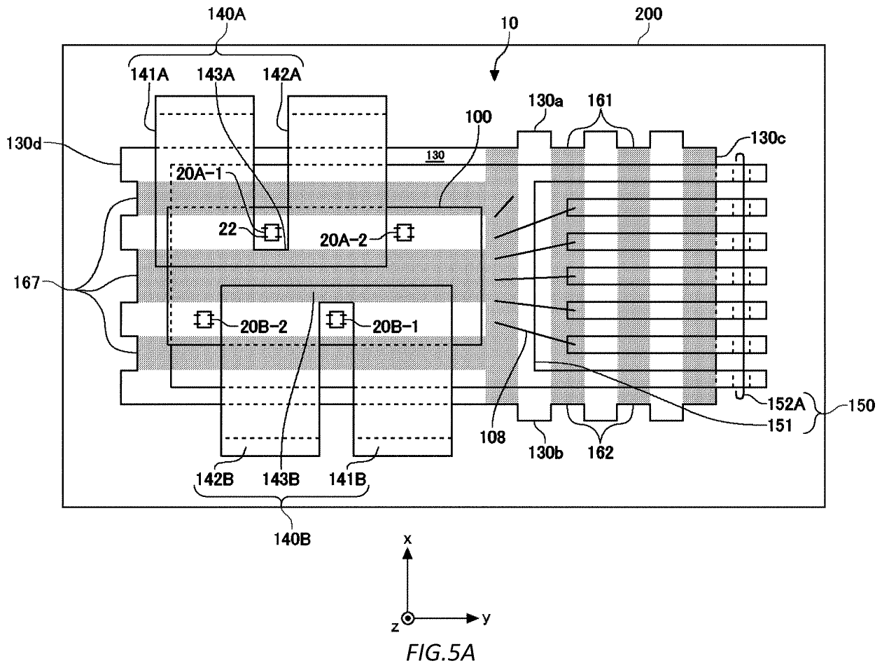

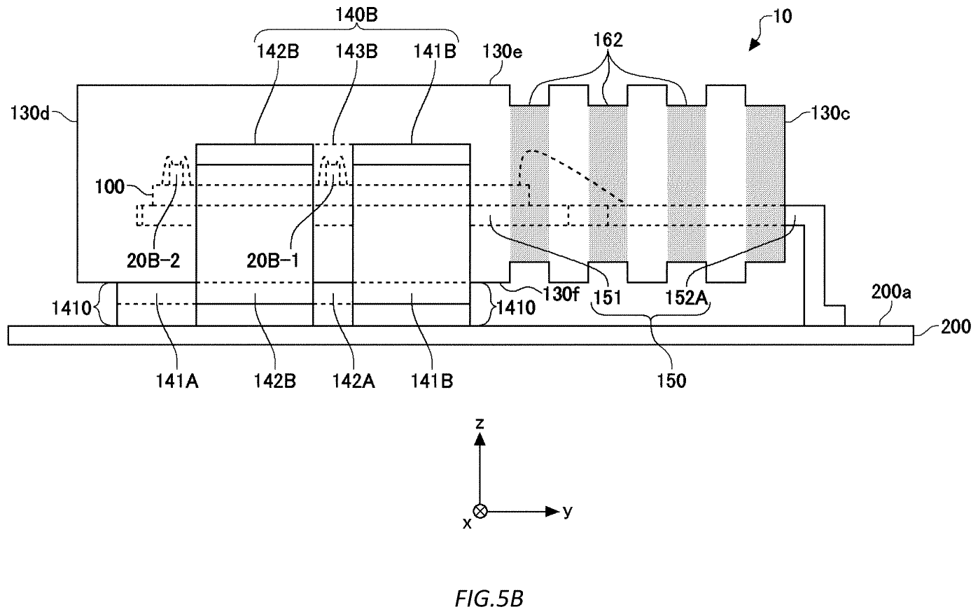

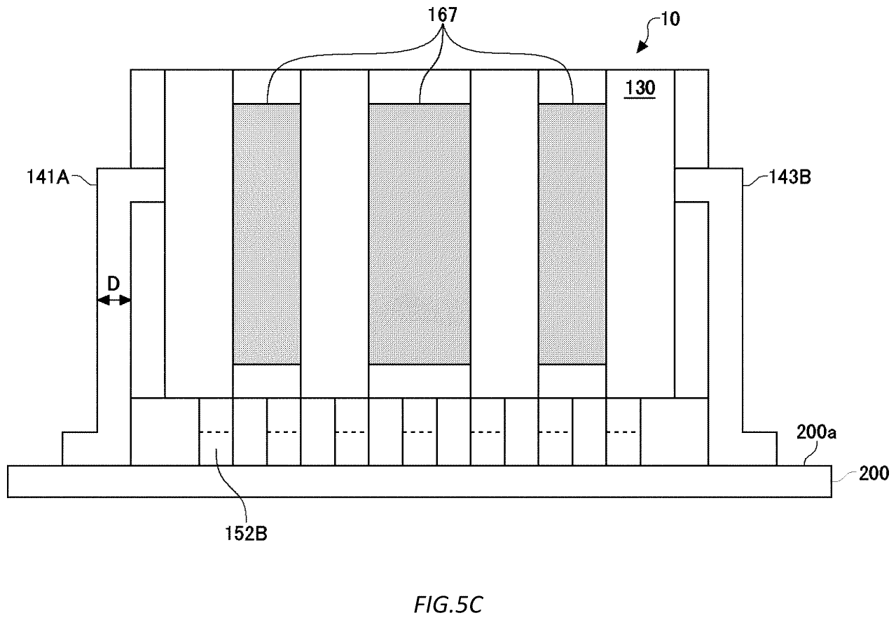

FIG. 5A is a schematic plan view of the current sensor 10 and the substrate 200 as viewed from the top surface side (positive z axis direction) according to a third embodiment. FIG. 5B is a side view of the current sensor 10 and the substrate 200 illustrated in FIG. 5A as viewed from the negative x axis direction. FIG. 5C is a side view of the current sensor 10 and the substrate 200 illustrated in FIG. 5A as viewed from the negative y axis direction. With regard to coordinates, in FIG. 5A, an orientation that is parallel and from bottom to top in relation to a paper surface is defined as an x axis direction, an orientation that is parallel and from left to right in relation to the paper surface is defined as a y axis direction, and an orientation that is perpendicular and from back to front in relation to the paper surface is defined as a z axis direction. Any one of axes of an x axis, a y axis, and a z axis are orthogonal to the other axes.

The current sensor 10 according to the third embodiment is different from the current sensor 10 according to the second embodiment in that the signal conductor 150 is exposed only from the surface 130c of the sealing section 130 an is not exposed from the surface 130d. The current sensor 10 according to the third embodiment is different from the current sensor 10 according to the second embodiment in that the signal conductor 150 does not have the terminal section 152B exposed from the surface 130d.

A mode of the grooves formed in the sealing section 130 are different from those of the current sensor 10 according to the first embodiment and the second embodiment.

The sealing section 130 has, in the surface 130a, at least one first groove 161 that intersects with the first path on the outer surface which has the shortest distance between the exposed portion of the conductor portion 142A that is the exposed portion of the current conductor 140A and the exposed portion of the terminal section 152A that is the exposed portion of the signal conductor 150 from the surface 130c. Furthermore, the sealing section 130 has, in the surface 130b, at least one second groove 162 that intersects with the second path on the outer surface of the sealing section 130 which has the shortest distance between the conductor portion 141B that is the exposed portion of the current conductor 140B and the exposed portion of the terminal section 152A that is the exposed portion of the signal conductor 150 from the surface 130c.

The first groove 161 extends along the z axis direction in the surface 130a and further reaches the surface 130e that is the top surface and the surface 130f that is the bottom surface, and thereafter extends along the x axis direction. Similarly, the second groove 162 extends along the z axis direction in the surface 130a and further reaches the surface 130e and the surface 130f, and thereafter extends along the x axis direction. The first groove 161 and the second groove 162 merge in a portion that extends along the x axis direction of the surface 130e and the surface 130f to form a single groove.

Furthermore, the sealing section 130 has, in the surface 130d, at least one fifth groove 167 that intersects with the third path on the outer surface of the sealing section 130 which has the shortest distance between the conductor portion 141A that is the exposed portion of the current conductor 140A and the conductor portion 142B that is the exposed portion of the current conductor 140B. The fifth groove 167 extends along the z axis direction in the surface 130d and further reaches the surface 130e and the surface 130f to extend along the y axis direction. The fifth groove 167 extends in the y axis direction in the surface 130e and the surface 130f and thereafter, on the surface 130e and the surface 130f, merges with the first groove 161 and the second groove 162 which extend in the x axis direction in the surface 130e and the surface 130f. Accordingly, the conductor portion 141A and the conductor portion 142A that are the exposed portions of the current conductor 140A are surrounded by the first groove 161 and the fifth groove 167. In addition, the conductor portion 141B and the conductor portion 142B that are the exposed portions of the current conductor 140B are surrounded by the second groove 162 and the fifth groove 167.

Herein, the current sensor 10 illustrated in FIG. 5A to FIG. 5C is of a front surface mounting type in which the current conductor 140A and the current conductor 140B are arranged on a mount surface of the substrate 200. Herein, when a slit or the like is provided in the substrate 200 to lengthen the creepage distance on the substrate 200 side, the sealing section 130 of the current sensor 10 may be sometimes better to be apart from the substrate 200 so as not to disturb the measure. That is, to avoid a dielectric breakdown via the front surface of the current sensor 10, the sealing section 130 may be sometimes better to be apart from the substrate 200. In view of the above, each portion exposed from the surface 130a of the sealing section 130 of the conductor portion 141A and the conductor portion 142A and each portion exposed from the surface 100b of the sealing section 130 of the conductor portion 141B and the conductor portion 142B have an extended portion 1410 which further extends in the z axis direction relative to the surface 130f of the sealing section 130 facing the surface 100b on the opposite side of the circuit surface of the signal processing IC 100. Since the extended portion 1410 is fixed to a mount surface 200a of the substrate 200, the sealing section 130 is located above the mount surface 200a. Accordingly a space can be provided between the sealing section 130 and the substrate 200. A distance between the mount surface 200a of the substrate 200 and the surface 130f facing the mount surface of the sealing section 130 is preferably 1 mm or more.

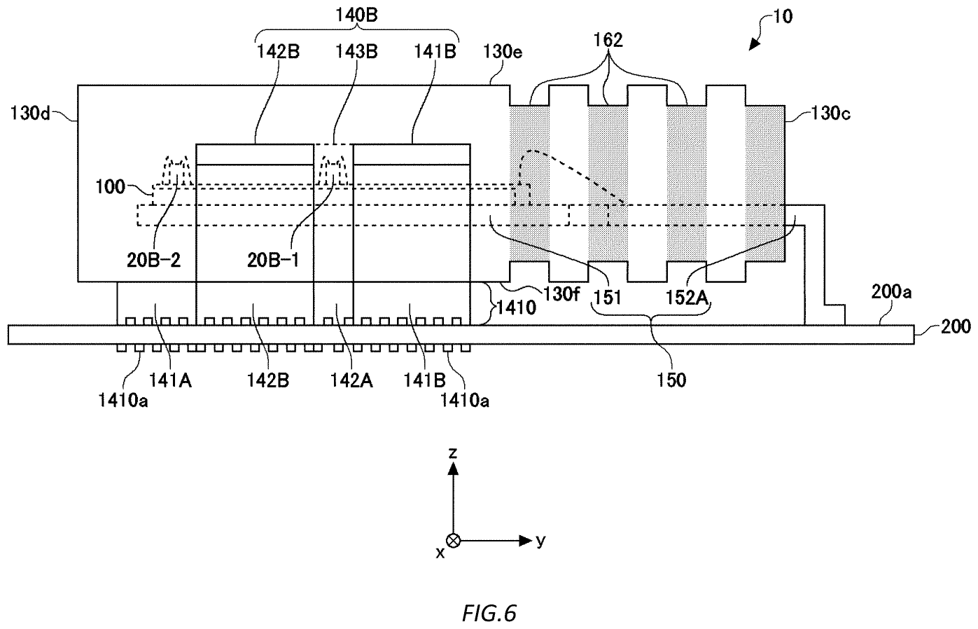

The current sensor 10 illustrated in FIG. 5A to FIG. 5C is an example of the front surface mounting type. The current sensor 10 illustrated in FIG. 1A to FIG. 1C and FIG. 4A to FIG. 4C is also an example of the front surface mounting type. However, the current sensor 10 may be of an insert mounting type in which the current conductor 140A and the current conductor 140B are inserted into the substrate 200. In the case of the insert mounting type, a direct electric connection is possible at a low resistance to a copper foil of an inner layer of the substrate 200 at the shortest distance from the current conductor 140A and the current conductor 140B, and as a result, it becomes possible to suppress heat generation of the substrate 200 to low. In addition, when the extended portion 1410 is inserted into the substrate 200, to certainly ensure a space between the mount surface 200a of the substrate 200 and the surface 130f of the sealing section 130, a width of a tip of the extended portion 1410 is preferably narrower than a width of a portion other than the tip of the extended portion 1410. The portion with the narrow width at the tip of the extended portion 1410 is inserted into the substrate 200, and the portion other than the tip of the extended portion 1410 comes into contact with the mount surface 100a of the substrate 200. Accordingly, the space between the mount surface 200a of the substrate 200 and the surface 130f of the sealing section 130 can be certainly ensured. For example, as illustrated in FIG. 6, the tip of the extended portion 1410 may include a plurality of tooth portions 1410a. Accordingly, since it becomes possible to take direct continuity with the inner layer of the substrate 200 while the tooth portions 1410a are inserted into a plurality of circular holes formed in the substrate 200, drilling into the substrate 200 can be easily performed, and also the heat generation of the substrate 200 can be further suppressed to low. For the drilling of the substrate 200, for example, a drill or the like can be used. A width of each of the plurality of tooth portions 1410a may be 0.5 times to 2 times a plate thickness D (illustrated in FIG. 5C) of each of the conductor portion 141A, the conductor portion 142A, the conductor portion 141B, and the conductor portion 142B. A cross section of the plurality of tooth portions 1410a may be square.

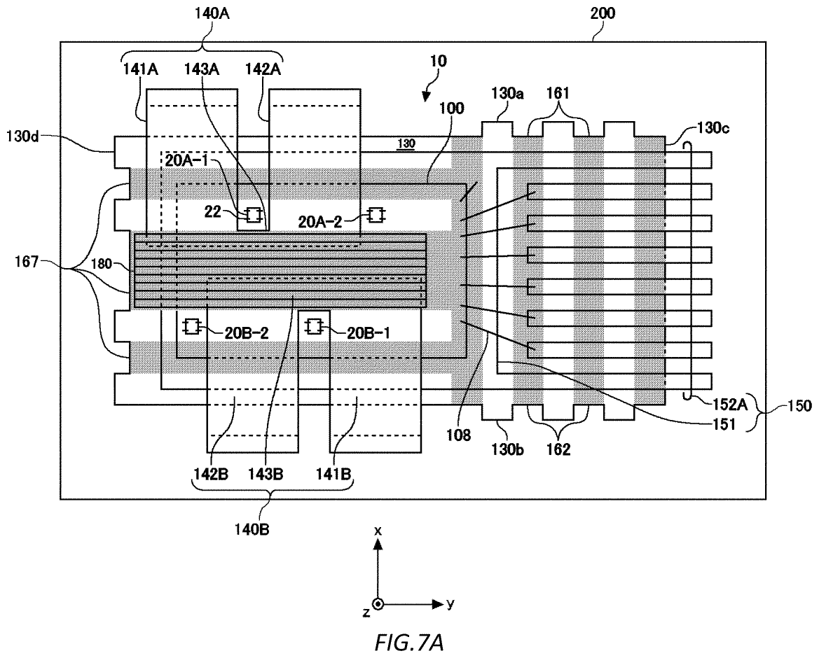

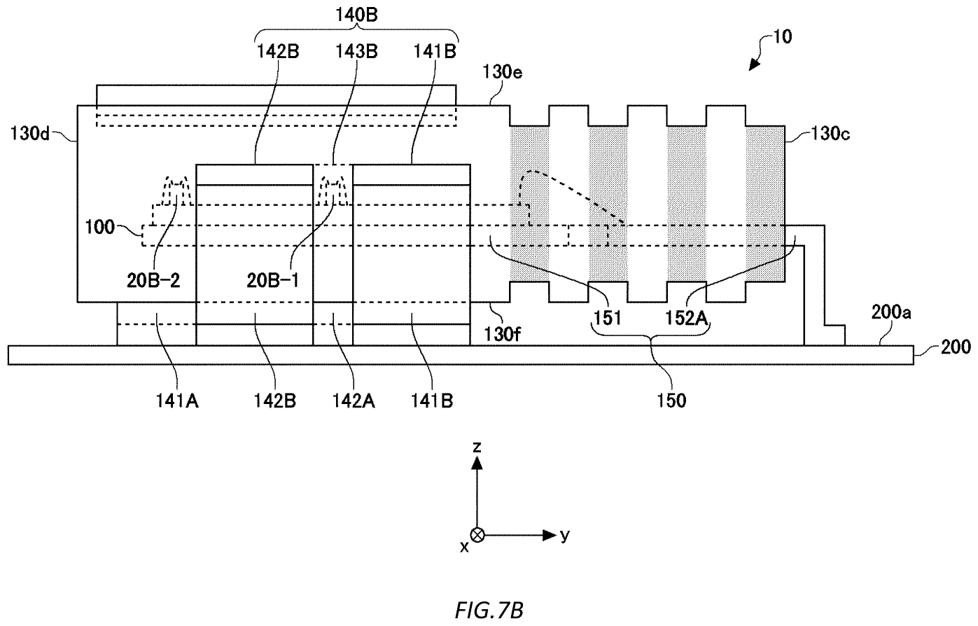

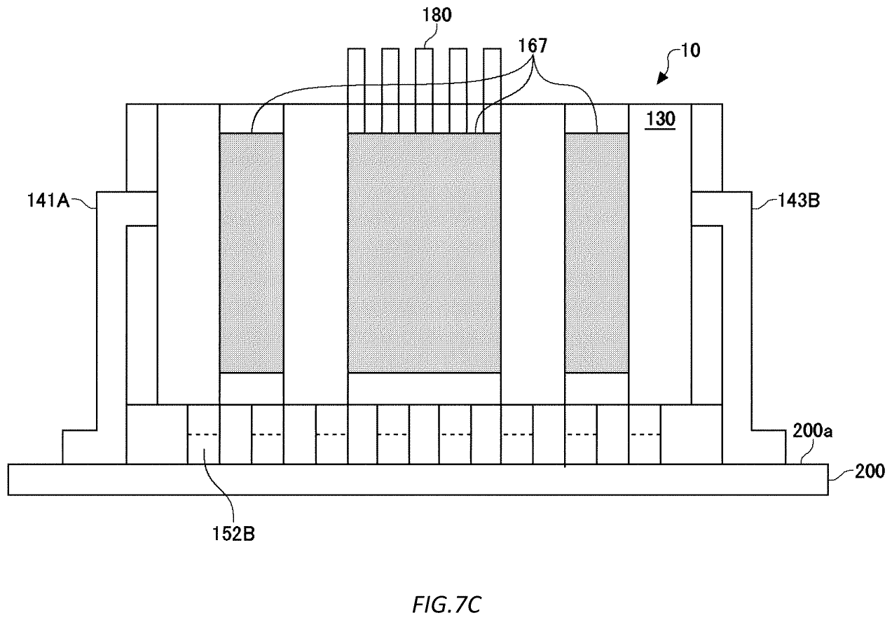

FIG. 7A is a schematic plan view of the current sensor 10 and the substrate 200 as viewed from the top surface side (positive z axis direction) according to a fourth embodiment. FIG. 7B is a side view of the current sensor 10 and the substrate 200 illustrated in FIG. 7A as viewed from the negative x axis direction. FIG. 7C is a side view of the current sensor 10 and the substrate 200 illustrated in FIG. 7A as viewed from the negative y axis direction.

The current sensor 10 according to the fourth embodiment is different from the current sensor 10 according to the third embodiment in that a heat sink 180 is mount in the fifth groove 167 in the central portion on the surface 130e among the plurality of the fifth grooves 167 of the sealing section 130. The heat sink 180 may be formed of a metal with a high thermal conductivity such as an aluminum alloy. Since the heat sink 180 is included, heat generated by the currents which flow through the current conductor 140A and the current conductor 140B built-in the sealing section 130 can be efficiently radiated to the outside. In addition, since the heat sink 180 is provided inside the groove of the fifth groove 167, an increase in a thickness of the current sensor 10 can be suppressed.

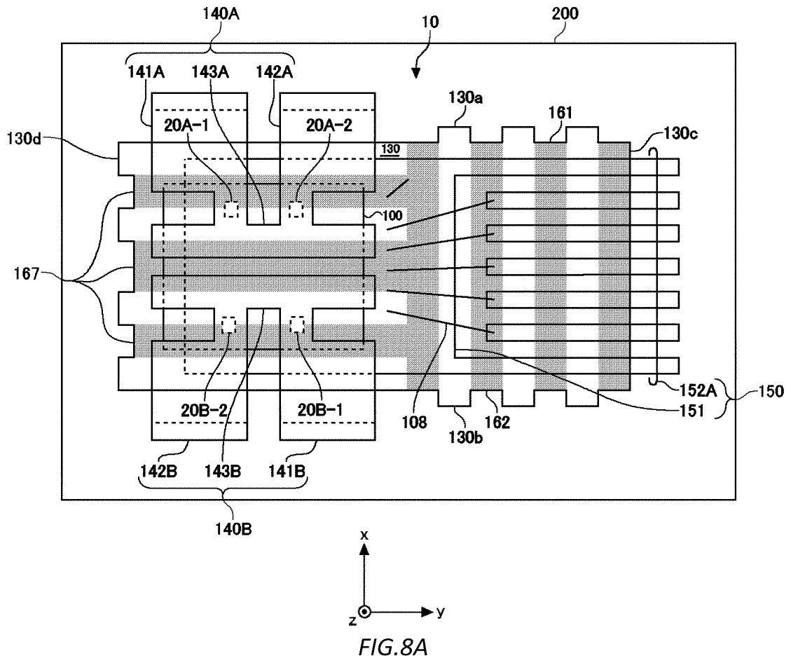

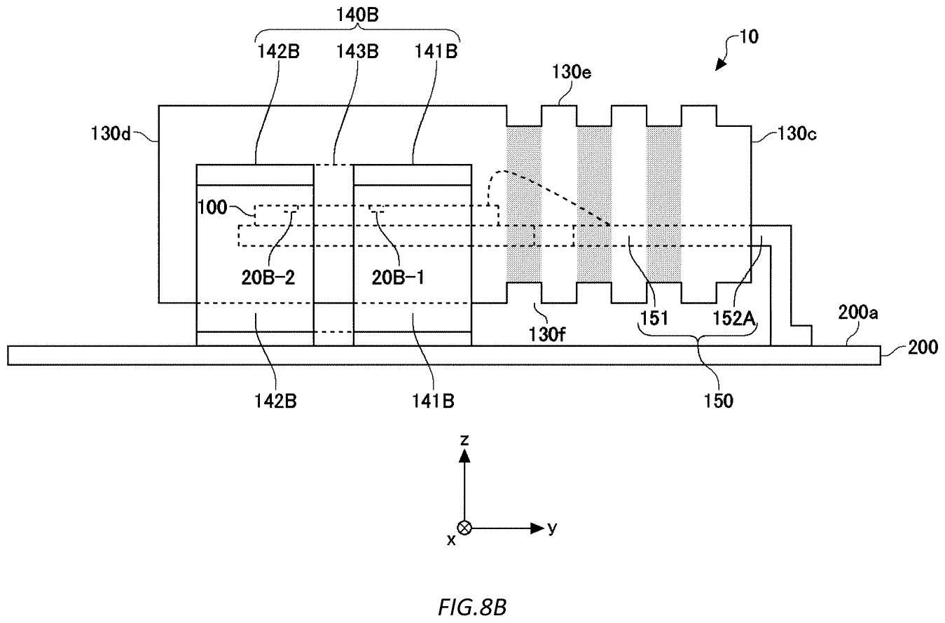

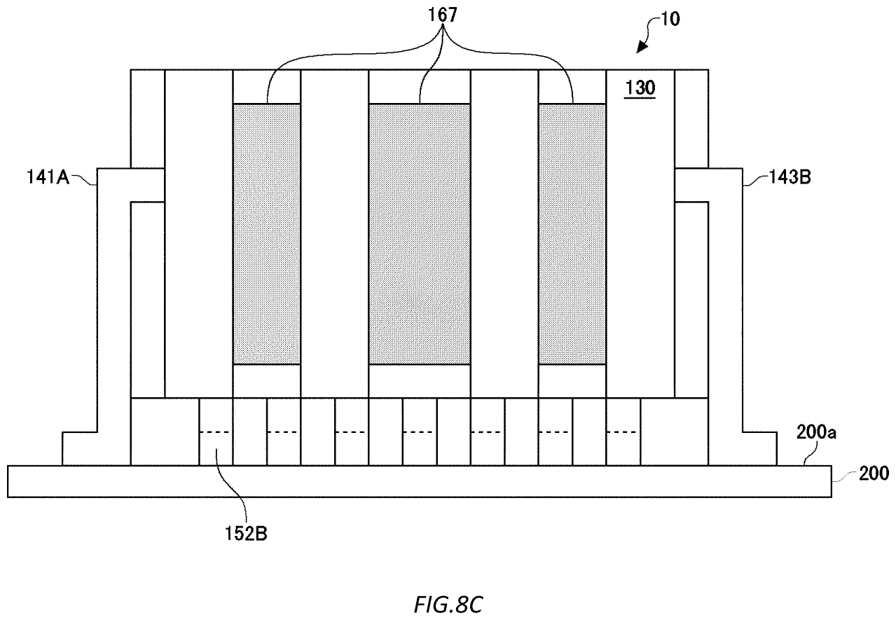

FIG. 8A is a schematic plan view of the current sensor 10 and the substrate 200 as viewed from the top surface side (positive z axis direction) according to a fifth embodiment. FIG. 8B is a side view of the current sensor 10 and the substrate 200 illustrated in FIG. 8A as viewed from the negative x axis direction. FIG. 8C is a side view of the current sensor 10 and the substrate 200 illustrated in FIG. 8A as viewed from the negative y axis direction. With regard to coordinates, in FIG. 8A, an orientation that is parallel and from bottom to top in relation to a paper surface is defined as an x axis direction, an orientation that is parallel and from left to right in relation to the paper surface is defined as a y axis direction, and an orientation that is perpendicular and from back to front in relation to the paper surface is defined as a z axis direction. Any one of axes of an x axis, a y axis, and a z axis are orthogonal to the other axes.

The current sensor 10 according to the fifth embodiment is different from the current sensor 10 according to the first embodiment to the fourth embodiment in that the magnetoelectric conversion element 20 is a magnetoresistance element. Furthermore, the current sensor 10 according to the fifth embodiment is different from the current sensor 10 according to the first embodiment to the fourth embodiment in that the magnetoelectric conversion element 20 is overlapped with the current conductor 140A or the current conductor 140B in plan view. The magnetoelectric conversion element 20 detects a magnetic field in either one axis direction on the xy plane. That is, the magnetoelectric conversion element 20 has the sensitivity axis in a direction along the magnetically sensitive surface. For example, the sensitivity axis may be the y axis direction. The magnetoelectric conversion element 20 may be a magnetoresistance element using a magnetoresistance effect. The magnetoresistance element may be, for example, a semiconductor magnetic resistor element (SMR), an anomalous magnetoresistive element (AMR), a giant magnetoresistive element (GMR), or a tunnel magnetoresistive element (TMR).

FIG. 8A illustrates the current sensor in which the magnetoelectric conversion element 20 is built in the signal processing IC 100, but similarly as in FIG. 7A or the like, the magnetoelectric conversion element 20 may be installed on the circuit surface instead of being built in the signal processing IC 100. That is, the current sensor 10 may have a monolithic structure with the magnetoelectric conversion element 20 built in the signal processing IC 100 or does not necessarily need to have the monolithic structure while the magnetoelectric conversion element 20 and the signal processing IC 100 are configured separately.

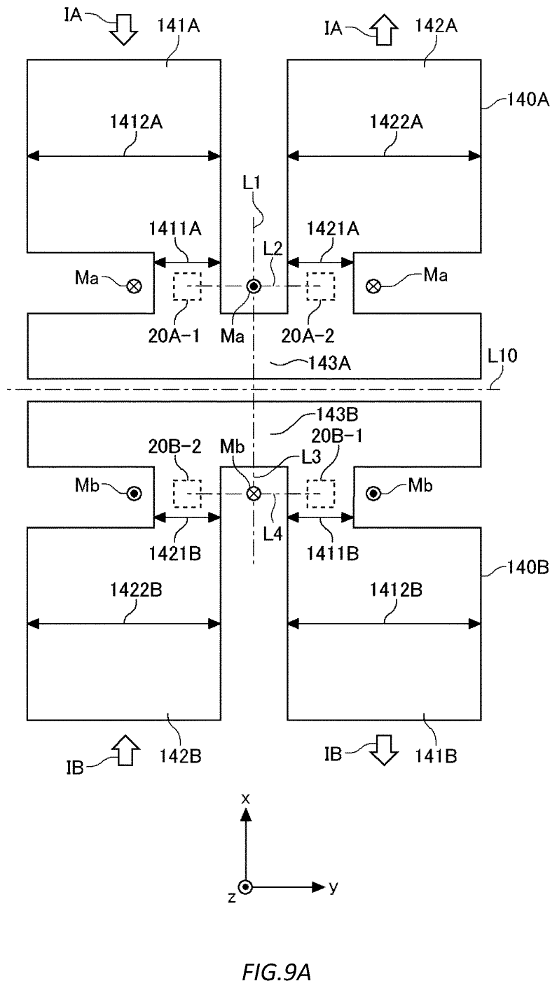

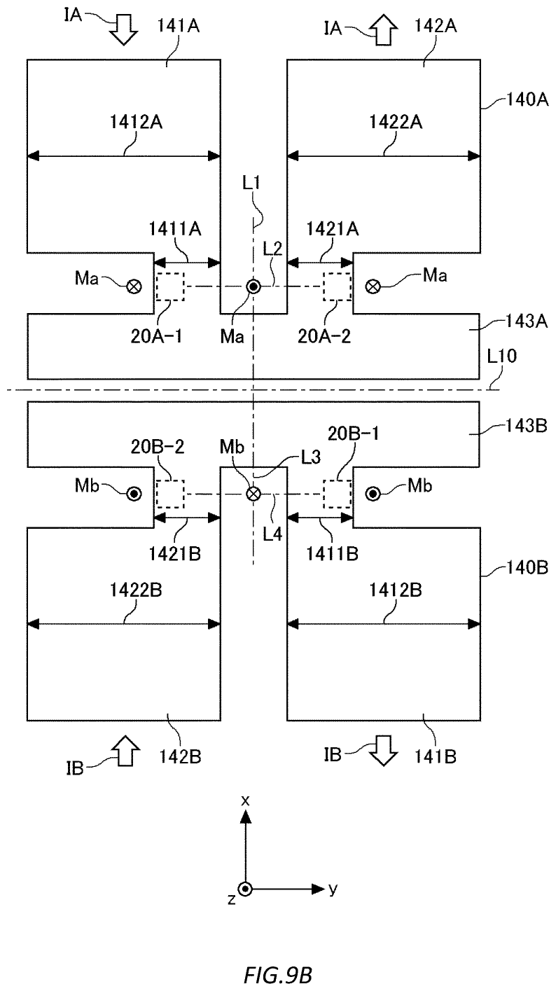

FIG. 9A is a diagram for describing a positional relationship between the magnetoelectric conversion element 20 and the current conductor 140A and the current conductor 140B.

The current conductor 140A and the current conductor 140B have a same shape. The current conductor 140A and the second current conductor may be arranged in a 180-degree rotated positional relationship in plan view. The current conductor 140B may be arranged in a position obtained by symmetrically moving the current conductor 140A with respect to a straight line L10 along the y direction as a symmetric axis in plan view. The magnetoelectric conversion element 20A-1 and the magnetoelectric conversion element 20A-2 are arranged in positions where a magnetic field in the y axis direction on the xy plane which is caused by the current to be measured which flows through the current conductor 140A is detected. The magnetoelectric conversion element 20A-1 and the magnetoelectric conversion element 20A-2 may be arranged in positions overlapped with the current conductor 140A in plan view. The magnetoelectric conversion element 20B-1 and the magnetoelectric conversion element 20B-2 are arranged in positions where a magnetic field in the y axis direction on the xy plane which is caused by a current to be measured Ib which flows through the current conductor 140B is detected. The magnetoelectric conversion element 20B-1 and the magnetoelectric conversion element 20B-2 may be arranged in positions overlapped with the current conductor 140A in plan view.

The magnetoelectric conversion element 20A-1 and the magnetoelectric conversion element 20A-2 are arranged facing each other in the y axis direction. The magnetoelectric conversion element 20B-1 and the magnetoelectric conversion element 20B-2 are arranged facing each other in the y axis direction. The entire magnetically sensitive surface of the magnetoelectric conversion element 20A-1 may be overlapped with the conductor portion 141A in plan view, and the entire magnetically sensitive surface of the magnetoelectric conversion element 20A-2 may be overlapped with the conductor portion 142A in plan view. The entire magnetically sensitive surface of the magnetoelectric conversion element 20B-1 may be overlapped with the conductor portion 141B in plan view, and the entire magnetically sensitive surface of the magnetoelectric conversion element 20B-2 may be overlapped with the conductor portion 142B in plan view.

The shape configured by the conductor portion 141A, the conductor portion 142A, and the conductor portion 143A may be line symmetric with respect to the perpendicular bisector L3, which is set as a symmetric axis, of the line segment L4 connecting the magnetoelectric conversion element 20B-1 and the magnetoelectric conversion element 20B-2 in plan view in a positional relationship between the magnetoelectric conversion element 20B-1 and the magnetoelectric conversion element 20B-2. The shape configured by the conductor portion 141B, the conductor portion 142B, and conductor portion 143C may be line symmetric with respect to the perpendicular bisector L1, which is set as a symmetric axis, of the line segment L2 connecting the magnetoelectric conversion element 20A-1 and the magnetoelectric conversion element 20A-2 in plan view in a positional relationship between the magnetoelectric conversion element 20A-1 and the magnetoelectric conversion element 20A-2.

The conductor portion 141A includes a portion 1411A overlapped with the magnetoelectric conversion element 20A-1 in plan view and a portion 1412A with a width in the y axis direction wider than the portion 1411A overlapped with the magnetoelectric conversion element 20A-2. The conductor portion 142A includes a portion 1421A overlapped with the magnetoelectric conversion element 20A-2 in plan view and a portion 1422A with a width in the y axis direction wider than the portion 1421A overlapped with the magnetoelectric conversion element 20A-2. The conductor portion 141B includes a portion 1411B overlapped with the magnetoelectric conversion element 20B-1 in plan view and a portion 1412B with a width in the y axis direction wider than the portion 1411B overlapped with the magnetoelectric conversion element 20B-1. The conductor portion 142B includes a portion 1421B overlapped with the magnetoelectric conversion element 20B-2 in plan view and a portion 1422B with a width in the y axis direction wider than the portion 1421B overlapped with the magnetoelectric conversion element 20B-2. Since the widths of the portions overlapped with the magnetoelectric conversion element 20 of the current conductors 140A and 140B are narrow, the magnetoelectric conversion element 20 can measure the currents which flow through the current conductors 140A and 140B in a highly sensitive manner.

The magnetoelectric conversion element 20A-1 may be arranged at a center of the width in the y axis direction of the portion 1411A overlapped with the magnetoelectric conversion element 20A-1 of the conductor portion 141A in plan view. The magnetoelectric conversion element 20A-2 may be arranged at a center of the width in the y axis direction of the portion 1421A overlapped with the magnetoelectric conversion element 20A-2 of the conductor portion 142A in plan view. The magnetoelectric conversion element 20B-1 may be arranged at a center of the width in the y axis direction of the portion 1411B overlapped with the magnetoelectric conversion element 20B-1 of the conductor portion 141B in plan view. The magnetoelectric conversion element 20B-2 may be arranged at a center of the width in the y axis direction of the portion 1421B overlapped with the magnetoelectric conversion element 20B-2 of the conductor portion 142B in plan view. Accordingly, the magnetoelectric conversion element 20 can measure the currents which flow through the current conductors 140A and 140B in a highly sensitive manner.

However, as illustrated in FIG. 9B, when the magnetoelectric conversion element 20 is arranged in a portion of the current conductor 140A or the current conductor 140B overlapped with the magnetoelectric conversion element 20 in plan view, the magnetoelectric conversion element 20 does not need to be arranged at the center of the portion.

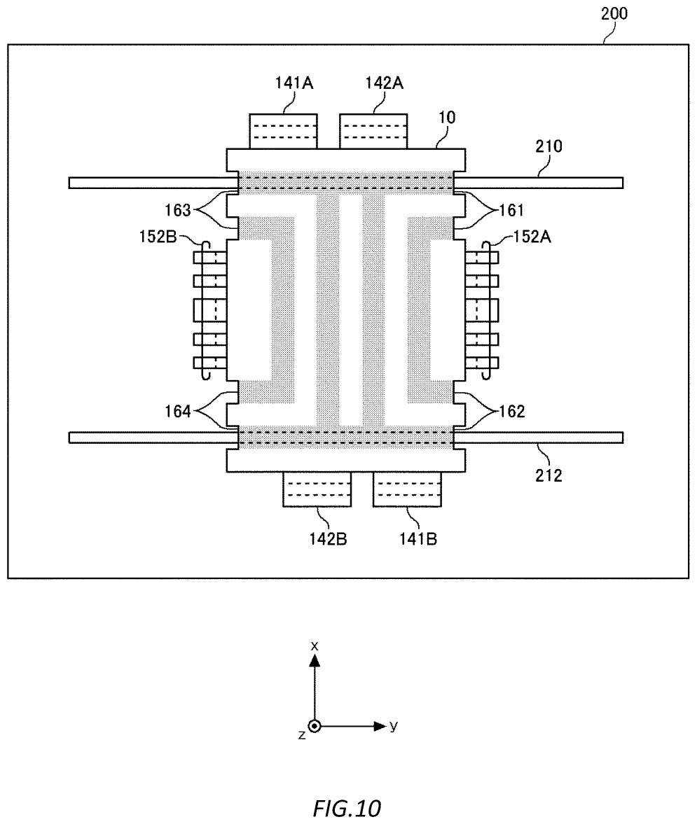

FIG. 10 is an example of a plan view of a state in which the current sensor 10 according to the second embodiment is implemented in the substrate 200. As illustrated in FIG. 10, the substrate 200 has a slit 210 and a slit 212 which extend along the y axis direction and pass through the substrate 200.

In plan view, the terminal section 152A and the terminal section 152B exist between the slit 210 and the slit 212. The slit 210 exists between the conductor portion 141A and the conductor portion 142A and the terminal section 152A and the terminal section 152B in plan view. The slit 212 exists between the conductor portion 141B and the conductor portion 142B and the terminal section 152A and the terminal section 152B in plan view.

The slit 210 may be provided in a position facing portions along the y axis direction of the first groove 161 and the third groove 163 in the surface 130f that is the bottom surface of the sealing section 130. The slit 212 may be provided in a position facing portions along the y axis direction of the second groove 162 and the fourth groove 164 in the surface 130f of the sealing section 130. The slit 210 and the slit 212 are longer the width in the y axis direction of the sealing section 130 in plan view. The slit 210 and the slit 212 further extend in the positive y axis direction and the negative y axis direction relative to the sides (the surface 130c or the surface 130d) of the sealing section 130 in plan view. The slit 210 and the slit 212 may further extend in the positive y axis direction and the negative y axis direction by at least 5 mm or more relative to the sides of the sealing section 130 in plan view. The widths of the slit 210 and the slit 212 may be 1 mm or more.

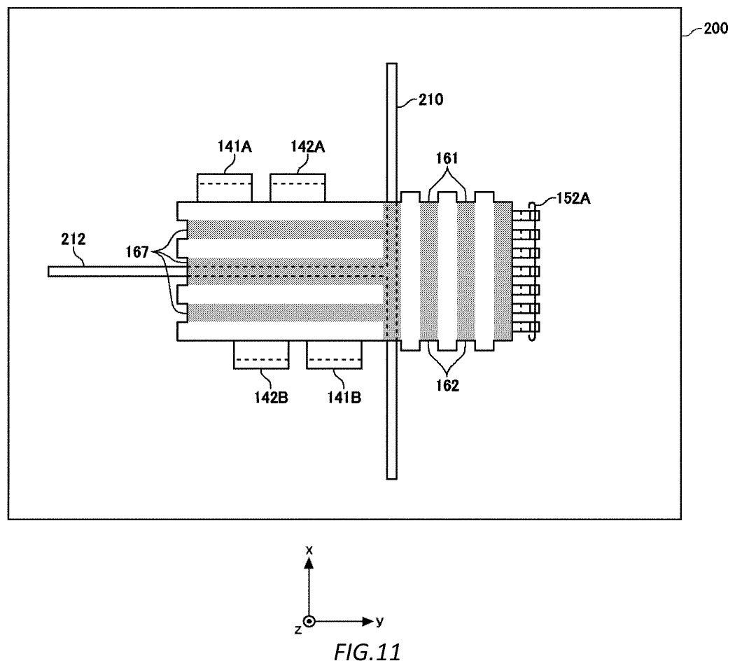

FIG. 11 is an example of a plan view of a state in which the current sensor 10 according to the third embodiment is implemented in the substrate 200. As illustrated in FIG. 11, the substrate 200 has the slit 210 which extends along the x axis direction and passes through the substrate 200 and the slit 212 which extends along the y axis direction and passes through the substrate 200.

The slit 210 exists between the terminal section 152A and the conductor portion 142A and the conductor portion 141B in plan view. The slit 212 exists between the conductor portion 141A and the conductor portion 142A and the conductor portion 141B and the conductor portion 142B in plan view. The slit 210 and the slit 212 may merge to form a T shape in plan view.

The slit 210 is longer than the width in the x axis direction of the sealing section 130 in plan view. The slit 210 further extends in the positive x axis direction and the negative x axis direction relative to the sides (the surface 130a and the surface 130b) of the sealing section 130 in plan view. The slit 212 further extends in the negative y axis direction relative to the side (surface 130b) of the sealing section 130 in plan view. The slit 210 may further extend in the positive x axis direction and the negative x axis direction by at least 5 mm or more relative to the side of the sealing section 130 in plan view. The slit 212 may further extend in the negative y axis direction by at least 5 mm or more relative to the side of the sealing section 130 in plan view. The widths of the slit 210 and the slit 212 may be 1 mm or more.

By providing the slit 210 and the slit 212 illustrated in FIG. 10 and FIG. 11 in the substrate 200, the insulation property between the current conductor 140A and the current conductor 140B and the terminal section 152A and the terminal section 152B can be more certainly ensured.

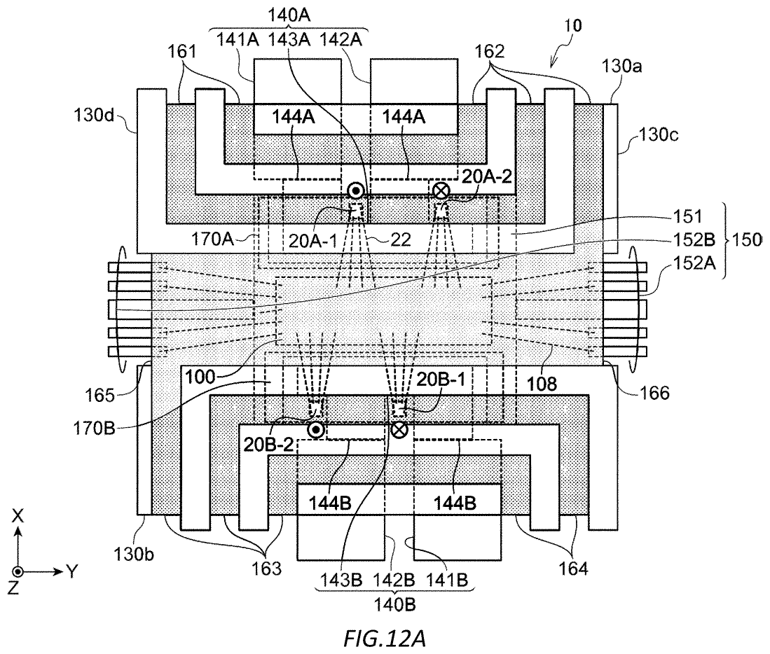

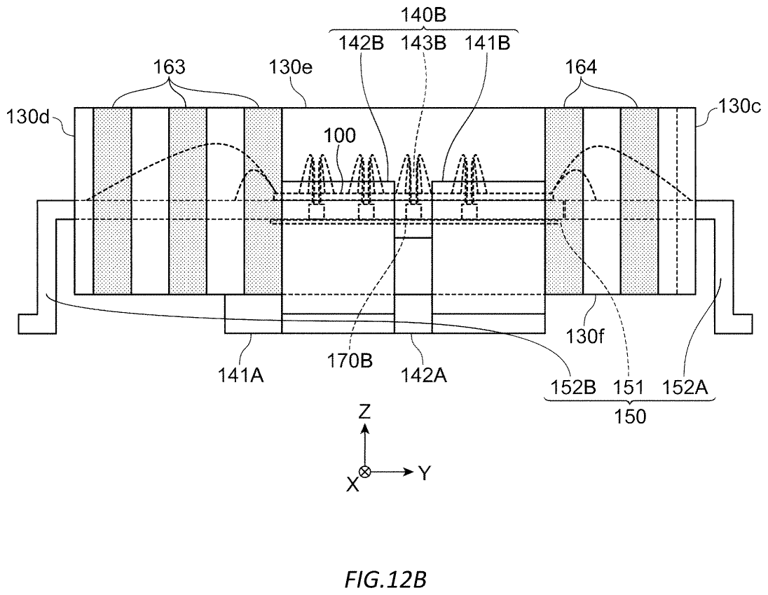

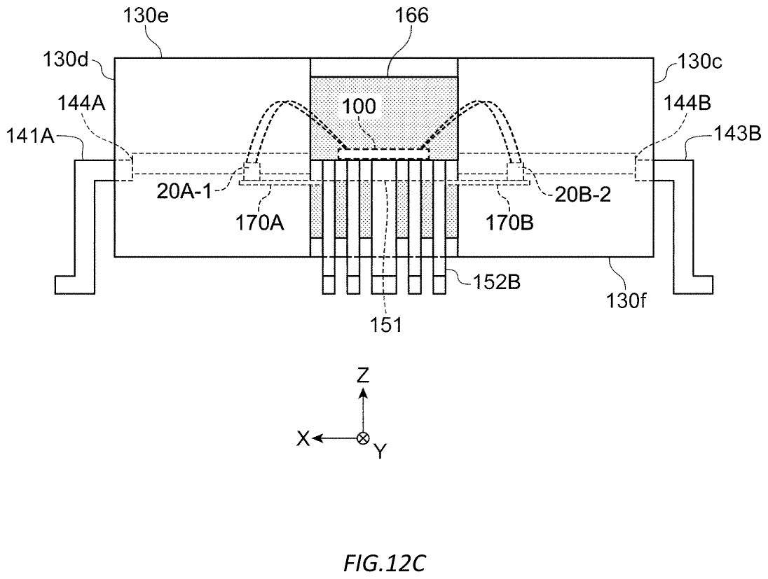

FIG. 12A is a schematic plan view of the current sensor 10 according to a sixth embodiment as viewed from the top surface side (positive z axis direction). FIG. 12B is a side view of the current sensor 10 illustrated in FIG. 12A as viewed from the negative x axis direction. FIG. 12C is a side view of the current sensor 10 illustrated in FIG. 12A as viewed from the negative y axis direction. With regard to coordinates, in FIG. 12A, an orientation that is parallel and from bottom to top in relation to a paper surface is defined as an x axis direction, an orientation that is parallel and from left to right in relation to the paper surface is defined as a y axis direction, and an orientation that is perpendicular and from back to front in relation to the paper surface is defined as a z axis direction. Any one of axes of an x axis, a y axis, and a z axis are orthogonal to the other axes.

Similarly as in the current sensor 10 according to the first embodiment, the magnetoelectric conversion element 20A-1 and the magnetoelectric conversion element 20A-2 are arranged on the support board 170A made of an insulating material such as a polyimide tape. The magnetoelectric conversion element 20B-1 and the magnetoelectric conversion element 20B-2 are arranged on the support board 170B made of an insulating material such as a polyimide tape. The support board 170A and the support board 170B are supported to the support section 151 of the signal conductor 150. The conductor portion 141A and the conductor portion 142A have the stepped section 144A so as to leave the signal conductor 150 in the z axis direction such that the current conductor 140A and the signal conductor 150 are not in contact in the z axis direction (thickness direction). The conductor portion 141B and the conductor portion 142B have the stepped section 144B so as to leave the signal conductor 150 in the z axis direction such that the current conductor 140B and the signal conductor 150 are not in contact in the z axis direction (thickness direction).

On the other hand, the current sensor 10 according to the sixth embodiment is different from the current sensor 10 according to the first embodiment in surfaces of the sealing section 130 in which parts of the first groove 161, the second groove 162, the third groove 163, and the fourth groove 164 are formed. The sealing section 130 has, in the surface 130a, at least one first groove 161 that intersects with the first path on the outer surface which has the shortest distance between the exposed portion of the conductor portion 141A that is the exposed portion of the current conductor 140A and the exposed portion of the terminal section 152B that is the exposed portion of the signal conductor 150 from the surface 130d. Furthermore, the sealing section 130 has, in the surface 130a, at least one second groove 162 that intersects with the second path on the outer surface of the sealing section 130 which has the shortest distance between the conductor portion 142A that is the exposed portion of the current conductor 140B and the exposed portion of the terminal section 152A that is the exposed portion of the signal conductor 150 from the surface 130c.

The first groove 161 extends along the z axis direction in the surface 130c and further reaches the surface 130e that is the top surface and the surface 130f that is the bottom surface to extend in the x axis direction, and thereafter extends along the y axis direction. Similarly, the second groove 162 extends along the z axis direction in the surface 130c and further reaches the surface 130e and the surface 130f to extend in the x axis direction, and thereafter extends along the y axis direction. The first groove 161 and the second groove 162 merge in a portion which extends along the y axis direction of the surface 130e and the surface 130f to form a single groove, and the conductor portion 141A and the conductor portion 142A exposed from the surface 130a are surrounded by the first groove 161 and the second groove 162.

The sealing section 130 has, in the surface 130b, at least one third groove 163 that intersects with the third path on the outer surface which has the shortest distance between the exposed portion of the conductor portion 142B that is the exposed portion of the current conductor 140B and the exposed portion of the terminal section 152B that is thee exposed portion of the signal conductor 150 from the surface 130d. Furthermore, the sealing section 130 has, in the surface 130b, at least one fourth groove 164 that intersects with the fourth path on the outer surface of the sealing section 130 which has the shortest distance between the conductor portion 141B that is the exposed portion of the current conductor 140B and the exposed portion of the terminal section 152A that is the exposed portion of the signal conductor 150 from the surface 130c.

The third groove 163 extends along the z axis direction in the surface 130b and further reaches the surface 130e and the surface 130f to extend in the x axis direction, and thereafter extends along the y axis direction. Similarly, the fourth groove 164 extends along the z axis direction in the surface 130b and further reaches the surface 130e and the surface 130f to extend in the x axis direction, and thereafter extends along the y axis direction. The third groove 163 and the fourth groove 164 merge in a portion which extends along the y axis direction of the surface 130e and the surface 130f to form a single groove, and the conductor portion 141B and the conductor portion 142B are surrounded by the third groove 163 and the fourth groove 164.

The sealing section 130 has a groove 166 which extends in the z axis direction in an exposed portion of the terminal section 152A at a central portion of the surface 130c. Furthermore, the sealing section 130 has a groove 165 which extends in the z axis direction in an exposed portion of the terminal section 152B at a central portion of the surface 130d. The groove 165 and the groove 166 extend along the z axis direction and further reach the surface 130e and the surface 130f to extend in the y axis direction, and merge with each other. The groove 165 merges with a part of the third groove 163 which extends in the x axis direction formed in the surface 130e and the surface 130f. The groove 166 merges with a part of the second groove 162 which extends in the x axis direction formed in the surface 130e and the surface 130f.

As described above, in accordance with the current sensor 10 according to the sixth embodiment, similarly as in the current sensor 10 according to the first embodiment, since the grooves are provided on the sides of the sealing section 130, in the current sensor 10 which includes the two current conductors 140A and 140B and can measure the currents to be measured for two channels, while the miniaturization is achieved, the creepage distance between the current conductor 140A and the current conductor 140B and the signal conductor 150 can be ensured.

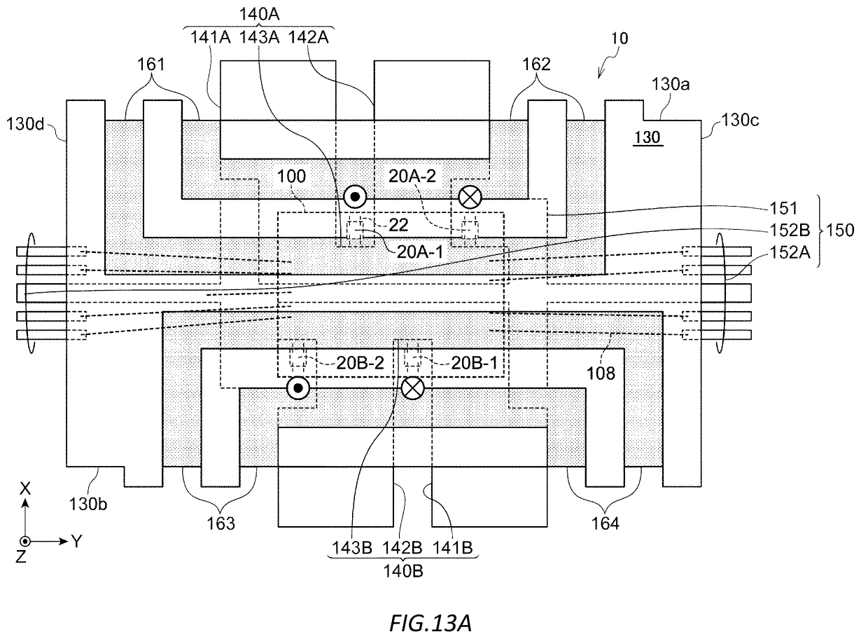

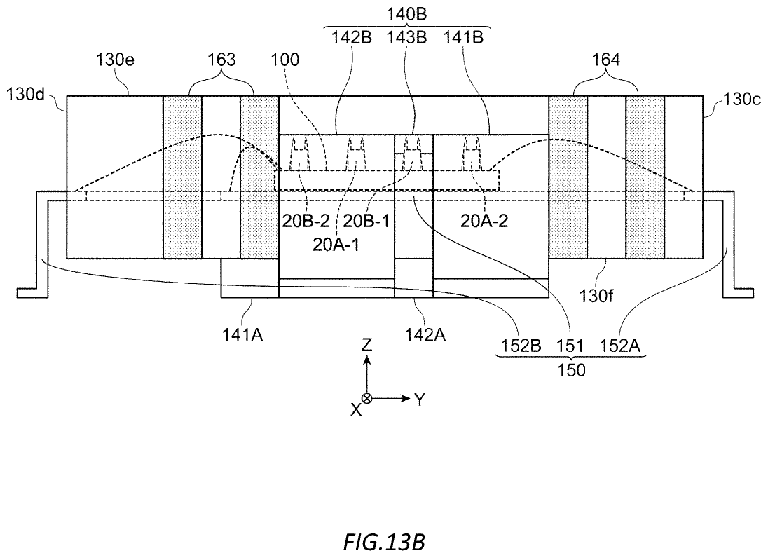

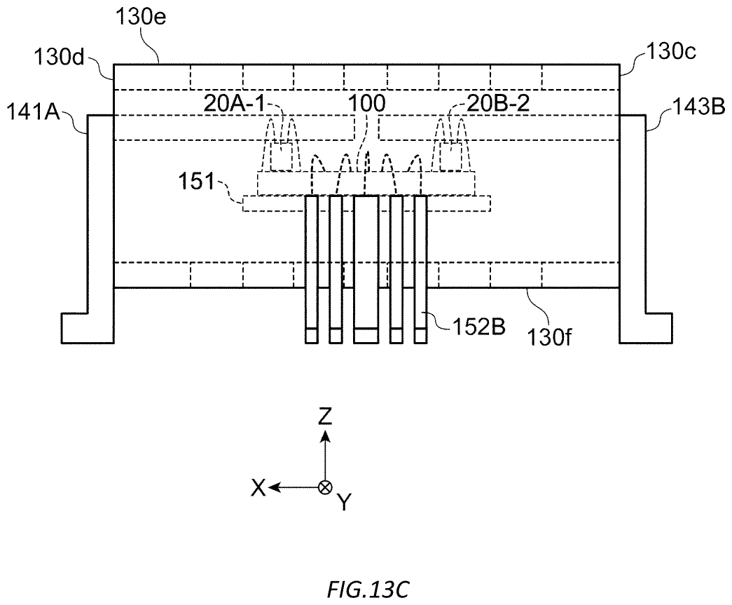

FIG. 13A is a schematic plan view of the current sensor 10 according to a seventh embodiment as viewed from the top surface side (positive z axis direction). FIG. 13B is a side view of the current sensor 10 illustrated in FIG. 13A as viewed from the negative x axis direction. FIG. 13C is a side view of the current sensor 10 illustrated in FIG. 13A as viewed from the negative y axis direction. With regard to coordinates, in FIG. 13A, an orientation that is parallel and from bottom to top in relation to a paper surface is defined as an x axis direction, an orientation that is parallel and from left to right in relation to the paper surface is defined as a y axis direction, and an orientation that is perpendicular and from back to front in relation to the paper surface is defined as a z axis direction. Any one of axes of an x axis, a y axis, and a z axis are orthogonal to the other axes.

Similarly as in the current sensor 10 according to the second embodiment, in the current sensor 10 according to the seventh embodiment, the magnetoelectric conversion element 20 is mounted on the surface 100a that is the circuit surface of the signal processing IC. Similarly as in the current sensor 10 according to the second embodiment, the magnetoelectric conversion element 20A-1 and the magnetoelectric conversion element 20A-2 are arranged in a region surrounded by the current conductor 140A in plan view. Similarly as in the current sensor 10 according to the second embodiment, the magnetoelectric conversion element 20B-1 and the magnetoelectric conversion element 20B-2 are arranged in a region surrounded by the current conductor 140B in plan view.

On the other hand, the current sensor 10 according to the seventh embodiment is different from the current sensor 10 according to the second embodiment in surfaces of the sealing section 130 in which parts of the first groove 161, the second groove 162, the third groove 163, and the fourth groove 164 are formed. The sealing section 130 has, in the surface 130a, at least one first groove 161 that intersects with the first path on the outer surface which has the shortest distance between the exposed portion of the conductor portion 141A that is the exposed portion of the current conductor 140A and the exposed portion of the terminal section 152B that is the exposed portion of the signal conductor 150 from the surface 130d. Furthermore, the sealing section 130 has, in the surface 130a, at least one second groove 162 that intersects with the second path on the outer surface of the sealing section 130 which has the shortest distance between the conductor portion 142A that is the exposed portion of the current conductor 140B and the exposed portion of the terminal section 152A that is the exposed portion of the signal conductor 150 from the surface 130c.

The first groove 161 extends along the z axis direction in the surface 130c and further reaches the surface 130e that is the top surface and the surface 130f that is the bottom surface to extend in the x axis direction, and thereafter extends along the y axis direction. Similarly, the second groove 162 extends along the z axis direction in the surface 130c and further reaches the surface 130e and the surface 130f to extend in the x axis direction, and thereafter extends along the y axis direction. The first groove 161 and the second groove 162 merge in a portion which extends along the y axis direction of the surface 130e and the surface 130f to form a single groove, and the conductor portion 141A and the conductor portion 142A exposed from the surface 130a are surrounded by the first groove 161 and the second groove 162.

The sealing section 130 has, in the surface 130b, at least one third groove 163 that intersects with the third path on the outer surface which has the shortest distance between the exposed portion of the conductor portion 142B that is the exposed portion of the current conductor 140B and the exposed portion of the terminal section 152B that is thee exposed portion of the signal conductor 150 from the surface 130d. Furthermore, the sealing section 130 has, in the surface 130b, at least one fourth groove 164 that intersects with the fourth path on the outer surface of the sealing section 130 which has the shortest distance between the conductor portion 141B that is the exposed portion of the current conductor 140B and the exposed portion of the terminal section 152A that is the exposed portion of the signal conductor 150 from the surface 130c.

The third groove 163 extends along the z axis direction in the surface 130b and further reaches the surface 130e and the surface 130f to extend in the x axis direction, and thereafter extends along the y axis direction. Similarly, the fourth groove 164 extends along the z axis direction in the surface 130b and further reaches the surface 130e and the surface 130f to extend in the x axis direction, and thereafter extends along the y axis direction. The third groove 163 and the fourth groove 164 merge in a portion which extends along the y axis direction of the surface 130e and the surface 130f to form a single groove, and the conductor portion 141B and the conductor portion 142B are surrounded by the third groove 163 and the fourth groove 164.

As described above, in accordance with the current sensor 10 according to the seventh embodiment, since the grooves are provided on the sides of the sealing section 130, in the current sensor 10 which includes the two current conductors 140A and 140B and can measure the currents to be measured for two channels, by mounting the magnetoelectric conversion element 20 to the circuit surface of the signal processing IC 100, similarly as in the current sensor 10 according to the second embodiment, while the distance between the current conductor 140A and the current conductor 140B is shortened to achieve a further miniaturization as compared with the current sensor 10 according to the first embodiment, the creepage distance between the current conductors 140A and 140B and the signal conductor 150 can be ensured.

While the present invention has been described by way of the embodiments above, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, steps, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

While the present invention has been described by way of the embodiments above, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, steps, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### Other Possible Items

### (Item 1)

A current sensor including:
a first current conductor through which a first current to be measured flows;
a first magnetoelectric conversion element which detects a magnetic field caused by the first current to be measured;
a second current conductor through which a second current to be measured flows;
a second magnetoelectric conversion element which detects a magnetic field caused by the second current to be measured;
a signal processing IC which processes signals output from the first magnetoelectric conversion element and the second magnetoelectric conversion element;
a signal conductor which is electrically coupled to the signal processing IC and transmits a signal output from the signal processing IC; and
a sealing section which seals a part of the first current conductor, the first magnetoelectric conversion element, a part of the second current conductor, the second magnetoelectric conversion element, the signal processing IC, and a part of the signal conductor,
in which
the part of the first current conductor is exposed from a first surface of the sealing section,
the part of the second current conductor is exposed from a second surface opposite to the first surface of the sealing section in a first direction,
the part of the signal conductor is exposed from a third surface adjacent to the first surface and the second surface of the sealing section along the first direction, and
the sealing section includes
a first groove formed along the first surface or the third surface.

### (Item 2)

The current sensor according to item 1, further including a second groove formed along the second surface or the third surface.

### (Item 3)

The current sensor according to item 2, in which
the sealing section includes a fourth surface opposite to the third surface in a second direction that intersects with the first direction, and a fifth surface and a sixth surface which are opposite to each other in a third direction that intersects with the first direction and the second direction, and
the first groove and the second groove include a portion along the third direction in the first surface or the third surface and a portion along at least the first direction in the fifth surface and the sixth surface.

### (Item 4)

The current sensor according to item 1, in which
the sealing section further includes
a fifth surface and a sixth surface which are opposite to each other in a third direction that intersects with the first direction and a second direction that intersects with the first direction, and
a groove which communicates so as to surround an exposed portion of the signal conductor from the third surface over the third surface, the fifth surface, and the sixth surface.

### (Item 5)

The current sensor according to item 2, in which
the sealing section includes
a fourth surface opposite to the third surface in a second direction that intersects with the first direction,
another part of the signal conductor is also exposed from the fourth surface, and
the sealing section includes
a third groove formed along the first surface or the fourth surface, and
a fourth groove formed along the second surface or the fourth surface.

### (Item 6)

The current sensor according to item 5, in which
the sealing section further includes
a fifth surface and a sixth surface which are opposite to each other in a third direction that intersects with the first direction and the second direction, and
a groove which communicates so as to surround an exposed portion of the signal conductor from the fourth surface over the fourth surface, the fifth surface, and the sixth surface,
the first groove and the second groove are provided in the third surface and are a part of the groove which communicates so as to surround the exposed portion of the signal conductor from the third surface, and
the third groove and the fourth groove are provided in the fourth surface and are a part of the groove which communicates so as to surround the exposed portion of the signal conductor from the fourth surface.

### (Item 7)

The current sensor according to item 1, in which
the sealing section includes a fourth surface opposite to the third surface in a second direction that intersects with the first direction, another part of the signal conductor is also exposed from the fourth surface, the sealing section includes a second groove formed along the second surface or the third surface, a third groove formed along the first surface or the fourth surface, and a fourth groove formed along the second surface or the fourth surface,
the sealing section includes a fifth surface and a sixth surface which are opposite to each other in a third direction that intersects with the first direction and the second direction, a groove which communicates so as to surround an exposed portion of the first current conductor from the first surface over the first surface, the fifth surface, and the sixth surface, and a groove which communicates so as to surround an exposed portion of the second current conductor from the second surface over the second surface, the fifth surface, and the sixth surface,
the first groove is provided in the first surface or the third surface,
the third groove is provided in the first surface or the fourth surface and is a part of the groove which communicates so as to surround the exposed portion of the first current conductor from the first surface,
the second groove is provided in the second surface or the third surface, and
the fourth groove is provided in the second surface or the fourth surface and is part of the groove which communicates so as to surround the exposed portion of the second current conductor from the second surface.

### (Item 8)

The current sensor according to item 6, in which
the first groove and the second groove include
a portion along the third direction in the third surface and a portion along the first direction and the second direction in the fifth surface and the sixth surface.

### (Item 9)

The current sensor according to item 2, in which
the sealing section includes a fourth surface opposite to the third surface in a second direction that intersects with the first direction, and a fifth surface and a sixth surface which are opposite to each other in a third direction that intersects with the first direction and the second direction,
the signal conductor is not exposed from the fourth surface, and
the sealing section includes a fifth groove formed along the fourth surface.

### (Item 10)

The current sensor according to item 9, further including:
a groove which communicate over the first surface, the second surface, the fifth surface, and the sixth surface, in which
the first groove and the second groove are a part of the groove.

### (Item 11)

The current sensor according to item 10, in which the fifth groove is a part of the groove.

### (Item 12)

The current sensor according to item 9, in which the fifth groove communicates over the fourth surface, the fifth surface, and the sixth surface.

### (Item 13)

The current sensor according to item 9, in which
the first groove includes a portion along the third direction in the first surface and a portion along the first direction in the fifth surface and the sixth surface,
the second groove includes a portion along the third direction in the second surface and a portion along the first direction in the fifth surface and the sixth surface, and
the portion along the first direction in the fifth surface and the sixth surface of the first groove and the portion along the first direction in the fifth surface and the sixth surface of the second groove merge.

### (Item 14)

The current sensor according to item 12, in which
the first groove includes a portion along the third direction in the first surface and a portion along the first direction in the fifth surface and the sixth surface,
the second groove includes a portion along the third direction in the second surface and a portion along the first direction in the fifth surface and the sixth surface,
the fifth groove includes a portion along the third direction in the fourth surface and a portion along the second direction in the fifth surface and the sixth surface,
the portion along the first direction in the fifth surface and the sixth surface of the first groove merges with the portion along the first direction in the fifth surface and the sixth surface of the second groove,
the portion along the second direction in the fifth surface and the sixth surface of the fifth groove merges with the first groove and the second groove,
an exposed portion of the first current conductor from the sealing section is surrounded by the fifth groove and the first groove, and
an exposed portion of the second current conductor from the sealing section is surrounded by the fifth groove and the second groove.

### (Item 15)

The current sensor according to item 14, further including:
a heat sink provided in the portion along the second direction of the fifth surface or the sixth surface of the sealing section.

### (Item 16)

The current sensor according to any one of items 1 to 15, in which the first magnetoelectric conversion element and the second magnetoelectric conversion element are arranged in a circuit surface of the signal processing IC.

### (Item 17)

The current sensor according to item 16, in which
the first current conductor includes a first conductor portion and a second conductor portion which extend in the first direction in plan view and are apart in a second direction that intersects with the first direction, and a third conductor portion which extends in the second direction and couples the first conductor portion and the second conductor portion,
the second current conductor includes a fourth conductor portion and a fifth conductor portion which extend in the first direction in plan view and are apart in the second direction, and a sixth conductor portion which extends in the second direction and couples the fourth conductor portion and the fifth conductor portion,
a part of the first conductor portion and the second conductor portion is exposed from the first surface of the sealing section, and
a part of the fourth conductor portion and the fifth conductor portion is exposed from the second surface of the sealing section.

### (Item 18)

The current sensor according to item 17, in which the third conductor portion and the sixth conductor portion face each other while being apart in plan view, and a space between the third conductor portion and the sixth conductor portion is filled with a resin material forming the sealing section.

### (Item 19)

The current sensor according to item 17, further including:
a third magnetoelectric conversion element arranged in the circuit surface of the signal processing IC while facing the first magnetoelectric conversion element across a part of the first conductor portion in plan view; and
a fourth magnetoelectric conversion element arranged in the circuit surface of the signal processing IC while facing the second magnetoelectric conversion element across a part of the fifth conductor portion in plan view,
in which
at least a part of the third magnetoelectric conversion element is positioned in a region surrounded by the first current conductor in plan view,
at least a part of the fourth magnetoelectric conversion element is positioned in a region surrounded by the second current conductor in plan view,
a distance between the first magnetoelectric conversion element and the sixth conductor portion is equal to a distance between the third magnetoelectric conversion element and the sixth conductor portion in plan view, and
a distance between the second magnetoelectric conversion element and the third conductor portion is equal to a distance between the fourth magnetoelectric conversion element and the third conductor portion in plan view.

### (Item 20)

The current sensor according to item 19, in which the first magnetoelectric conversion element, the second magnetoelectric conversion element, the third magnetoelectric conversion element, and the fourth magnetoelectric conversion element are built in a chip configuring the signal processing IC.

### (Item 21)

The current sensor according to item 17, further including:
a third magnetoelectric conversion element arranged in the circuit surface of the signal processing IC while facing the first magnetoelectric conversion element across the second conductor portion in plan view; and
a fourth magnetoelectric conversion element arranged in the circuit surface of the signal processing IC while facing the second magnetoelectric conversion element across the fourth conductor portion in plan view,
in which
the first magnetoelectric conversion element is positioned in a region surround by the first current conductor in plan view,
the second magnetoelectric conversion element is positioned in a region surround by the second current conductor in plan view,
a distance between the first magnetoelectric conversion element and the sixth conductor portion is equal to a distance between the third magnetoelectric conversion element and the sixth conductor portion in plan view,
a distance between the second magnetoelectric conversion element and the third conductor portion is equal to a distance between the fourth magnetoelectric conversion element and the third conductor portion in plan view, and
the first magnetoelectric conversion element, the second magnetoelectric conversion element, the third magnetoelectric conversion element, and the fourth magnetoelectric conversion element have a sensitivity axis in a third direction that intersects with the first direction and the second direction.

### (Item 22)

The current sensor according to item 21, in which the first magnetoelectric conversion element, the second magnetoelectric conversion element, the third magnetoelectric conversion element, and the fourth magnetoelectric conversion element are built in a chip configuring the signal processing IC.

### (Item 23)

The current sensor according to item 21, in which
the first magnetoelectric conversion element is positioned on an extending line on which the fourth conductor portion extends in plan view,
the third magnetoelectric conversion element is positioned on an extending line on which the fifth conductor portion extends in plan view,
the second magnetoelectric conversion element is positioned on an extending line on which the second conductor portion extends in plan view, and
the fourth magnetoelectric conversion element is positioned on an extending line on which the first conductor portion extends in plan view.

### (Item 24)

The current sensor according to item 23, in which
the first magnetoelectric conversion element is positioned on a perpendicular bisector of a line segment which connects the second magnetoelectric conversion element and the fourth magnetoelectric conversion element in plan view, and
the second magnetoelectric conversion element is positioned on a perpendicular bisector of a line segment which connects the first magnetoelectric conversion element and the third magnetoelectric conversion element in plan view.

### (Item 25)

The current sensor according to item 21, in which the first magnetoelectric conversion element, the second magnetoelectric conversion element, the third magnetoelectric conversion element, and the fourth magnetoelectric conversion element are each a Hall element which has a sensitivity axis in a direction that intersects with a magnetically sensitive surface and uses a Hall effect.

### (Item 26)

The current sensor according to item 17, in which
the first current conductor and the second current conductor have a same shape,
the first current conductor and the second current conductor are arranged in a 180-degree rotated positional relationship in plan view,
the current sensor further includes
a third magnetoelectric conversion element arranged facing the first magnetoelectric conversion element in the second direction, and
a fourth magnetoelectric conversion element arranged facing the second magnetoelectric conversion element in the second direction,
an entire magnetically sensitive surface of the first magnetoelectric conversion element overlaps with the first conductor portion in plan view,
an entire magnetically sensitive surface of the third magnetoelectric conversion element overlaps with the second conductor portion in plan view,
an entire magnetically sensitive surface of the second magnetoelectric conversion element overlaps with the fourth conductor portion in plan view,
an entire magnetically sensitive surface of the fourth magnetoelectric conversion element overlaps with the fifth conductor portion in plan view, and
the first magnetoelectric conversion element, the second magnetoelectric conversion element, the third magnetoelectric conversion element, and the fourth magnetoelectric conversion element have a sensitivity axis in the second direction

### (Item 27)

The current sensor according to item 26, in which
the first magnetoelectric conversion element, the second magnetoelectric conversion element, the third magnetoelectric conversion element, and the fourth magnetoelectric conversion element are built in a chip configuring the signal processing IC.

### (Item 28)

A current sensor module including:
the current sensor according to any one of items 5 to 8; and
a substrate to which the current sensor is mounted, in which
the substrate has a first slit and a second slit which extend in a second direction that intersects with the first direction,
in plan view, an exposed portion of the signal conductor from the sealing section exists between the first slit and the second slit, and also the first slit exists between an exposed portion of the first current conductor from the sealing section and an exposed portion of the signal conductor from the sealing section, and the second slit exists between an exposed portion of the second current conductor from the sealing section and an exposed portion of the signal conductor from the sealing section, and
the first slit and the second slit extend on an outer side relative to the third surface and the fourth surface of the sealing section in plan view.

### (Item 29)

The current sensor module according to item 28, in which
the current sensor further includes a second groove formed along the second surface or the third surface, and
the first slit and the second slit are arranged in at least positions which face portions of the first groove and the second groove of the sealing section along the second direction facing the substrate.

### (Item 30)

A current sensor module including:
the current sensor according to any one of items 9 to 15; and
a substrate to which the current sensor is mounted, in which the substrate includes a first slit which extends in the first direction and a second slit which extends in a second direction that intersects with the first direction,
the first slit exists between an exposed portion of the first current conductor from the sealing section and an exposed portion of the second current conductor from the sealing section and an exposed portion of the signal conductor from the sealing section and extends on an outer side relative to the first surface and the second surface of the sealing section in plan view, and
the second slit exists between an exposed portion of the first current conductor from the sealing section and an exposed portion of the second current conductor from the sealing section and extends on an outer side relative to the fourth surface of the sealing section in plan view.

### (Item 31)

The current sensor module according to item 30, in which
the first slit is arranged in at least a position facing a portion of the first groove and the second groove of the sealing section, the portion facing the substrate and being along the first direction,
the second slit is arranged in at least a position facing a portion of the fifth groove of the sealing section, the portion facing the substrate and being along the second direction, and
the first slit and the second slit communicate.

### EXPLANATION OF REFERENCES

10: current sensor;
20, 20A-1, 20A-2, 20B-1, 20B-2: magnetoelectric conversion element;
22, 108: wire;
100: signal processing IC;
130: sealing section;
140A, 140B: current conductor;
141A, 142A, 143A: conductor portion;
141B, 142B, 143B: conductor portion;
144A, 144B, 154: stepped section;
145A, 145B: extended portion;
150: signal conductor;
151: support section;
152A, 152B: terminal section;
161, 162, 163, 164, 165, 166, 167: groove;
170A, 170B: support board;
180: heat sink;
200: substrate;
210, 212: slit;
212: slit;
1410: extended portion; and
1410a: tooth portion.

What is claimed is:

1. A current sensor comprising:
a first current conductor through which a first current to be measured flows;
a first magnetoelectric conversion element which detects a magnetic field caused by the first current to be measured;
a second current conductor through which a second current to be measured flows;
a second magnetoelectric conversion element which detects a magnetic field caused by the second current to be measured;
a signal processing IC which processes signals output from the first magnetoelectric conversion element and the second magnetoelectric conversion element;
a signal conductor which is electrically coupled to the signal processing IC and transmits a signal output from the signal processing IC; and
a sealing section which seals a part of the first current conductor, the first magnetoelectric conversion element, a part of the second current conductor, the second magnetoelectric conversion element, the signal processing IC, and a part of the signal conductor, wherein
the part of the first current conductor is exposed from a first surface of the sealing section,
the part of the second current conductor is exposed from a second surface opposite to the first surface of the sealing section in a first direction,
the part of the signal conductor is exposed from a third surface adjacent to the first surface and the second surface of the sealing section along the first direction, and
the sealing section includes
a first groove formed along the first surface or the third surface.

2. The current sensor according to claim 1, further comprising a second groove formed along the second surface or the third surface.

3. The current sensor according to claim 2, wherein
the sealing section includes a fourth surface opposite to the third surface in a second direction that intersects with the first direction, and a fifth surface and a sixth surface which are opposite to each other in a third direction that intersects with the first direction and the second direction, and
the first groove and the second groove include a portion along the third direction in the first surface or the third surface and a portion along at least the first direction in the fifth surface and the sixth surface.

4. The current sensor according to claim 1, wherein
the sealing section further includes
a fifth surface and a sixth surface which are opposite to each other in a third direction that intersects with the first direction and a second direction that intersects with the first direction, and
a groove which communicates so as to surround an exposed portion of the signal conductor from the third surface over the third surface, the fifth surface, and the sixth surface.

5. The current sensor according to claim 2, wherein
the sealing section includes
a fourth surface opposite to the third surface in a second direction that intersects with the first direction,
another part of the signal conductor is also exposed from the fourth surface, and
the sealing section includes
a third groove formed along the first surface or the fourth surface, and
a fourth groove formed along the second surface or the fourth surface.

6. The current sensor according to claim 5, wherein
the sealing section further includes
a fifth surface and a sixth surface which are opposite to each other in a third direction that intersects with the first direction and the second direction, and
a groove which communicates so as to surround an exposed portion of the signal conductor from the fourth surface over the fourth surface, the fifth surface, and the sixth surface,
the first groove and the second groove are provided in the third surface and are a part of the groove which communicates so as to surround the exposed portion of the signal conductor from the third surface, and
the third groove and the fourth groove are provided in the fourth surface and are a part of the groove which communicates so as to surround the exposed portion of the signal conductor from the fourth surface.

7. The current sensor according to claim 1, wherein
the sealing section includes a fourth surface opposite to the third surface in a second direction that intersects with the first direction, another part of the signal conductor is also exposed from the fourth surface, the sealing section includes a second groove formed along the second surface or the third surface, a third groove formed along the first surface or the fourth surface, and a fourth groove formed along the second surface or the fourth surface,
the sealing section includes a fifth surface and a sixth surface which are opposite to each other in a third direction that intersects with the first direction and the second direction, a groove which communicates so as to surround an exposed portion of the first current conductor from the first surface over the first surface, the fifth surface, and the sixth surface, and a groove which communicates so as to surround an exposed portion of the second current conductor from the second surface over the second surface, the fifth surface, and the sixth surface,
the first groove is provided in the first surface or the third surface,
the third groove is provided in the first surface or the fourth surface and is a part of the groove which communicates so as to surround the exposed portion of the first current conductor from the first surface,
the second groove is provided in the second surface or the third surface, and
the fourth groove is provided in the second surface or the fourth surface and is part of the groove which communicates so as to surround the exposed portion of the second current conductor from the second surface.

8. The current sensor according to claim 6, wherein
the first groove and the second groove include
a portion along the third direction in the third surface and a portion along the first direction and the second direction in the fifth surface and the sixth surface.

9. The current sensor according to claim 2, wherein
the sealing section includes a fourth surface opposite to the third surface in a second direction that intersects with the first direction, and a fifth surface and a sixth surface which are opposite to each other in a third direction that intersects with the first direction and the second direction,
the signal conductor is not exposed from the fourth surface, and
the sealing section includes a fifth groove formed along the fourth surface.

10. The current sensor according to claim 9, further comprising:
a groove which communicate over the first surface, the second surface, the fifth surface, and the sixth surface, wherein
the first groove and the second groove are a part of the groove.

11. The current sensor according to claim 10, wherein the fifth groove is a part of the groove.

12. The current sensor according to claim 9, wherein the fifth groove communicates over the fourth surface, the fifth surface, and the sixth surface.

13. The current sensor according to claim 9, wherein
the first groove includes a portion along the third direction in the first surface and a portion along the first direction in the fifth surface and the sixth surface,
the second groove includes a portion along the third direction in the second surface and a portion along the first direction in the fifth surface and the sixth surface, and
the portion along the first direction in the fifth surface and the sixth surface of the first groove and the portion along the first direction in the fifth surface and the sixth surface of the second groove merge.

14. The current sensor according to claim 12, wherein
the first groove includes a portion along the third direction in the first surface and a portion along the first direction in the fifth surface and the sixth surface,
the second groove includes a portion along the third direction in the second surface and a portion along the first direction in the fifth surface and the sixth surface,
the fifth groove includes a portion along the third direction in the fourth surface and a portion along the second direction in the fifth surface and the sixth surface,
the portion along the first direction in the fifth surface and the sixth surface of the first groove merges with the portion along the first direction in the fifth surface and the sixth surface of the second groove,
the portion along the second direction in the fifth surface and the sixth surface of the fifth groove merges with the first groove and the second groove,
an exposed portion of the first current conductor from the sealing section is surrounded by the fifth groove and the first groove, and
an exposed portion of the second current conductor from the sealing section is surrounded by the fifth groove and the second groove.

15. The current sensor according to claim 14, further comprising:
a heat sink provided in the portion along the second direction of the fifth surface or the sixth surface of the sealing section.

16. The current sensor according to claim 1, wherein the first magnetoelectric conversion element and the second magnetoelectric conversion element are arranged in a circuit surface of the signal processing IC.

17. The current sensor according to claim 16, wherein the first current conductor includes a first conductor portion and a second conductor portion which extend in the first direction in plan view and are apart in a second direction that intersects with the first direction, and a third conductor portion which extends in the second direction and couples the first conductor portion and the second conductor portion,
the second current conductor includes a fourth conductor portion and a fifth conductor portion which extend in the first direction in plan view and are apart in the second direction, and a sixth conductor portion which extends in the second direction and couples the fourth conductor portion and the fifth conductor portion,
a part of the first conductor portion and the second conductor portion is exposed from the first surface of the sealing section, and
a part of the fourth conductor portion and the fifth conductor portion is exposed from the second surface of the sealing section.

18. The current sensor according to claim 17, wherein the third conductor portion and the sixth conductor portion face each other while being apart in plan view, and a space between the third conductor portion and the sixth conductor portion is filled with a resin material forming the sealing section.

19. The current sensor according to claim 17, further comprising:
a third magnetoelectric conversion element arranged in the circuit surface of the signal processing IC while facing the first magnetoelectric conversion element across a part of the first conductor portion in plan view; and
a fourth magnetoelectric conversion element arranged in the circuit surface of the signal processing IC while facing the second magnetoelectric conversion element across a part of the fifth conductor portion in plan view, wherein
at least a part of the third magnetoelectric conversion element is positioned in a region surrounded by the first current conductor in plan view,
at least a part of the fourth magnetoelectric conversion element is positioned in a region surrounded by the second current conductor in plan view,
a distance between the first magnetoelectric conversion element and the sixth conductor portion is equal to a distance between the third magnetoelectric conversion element and the sixth conductor portion in plan view, and
a distance between the second magnetoelectric conversion element and the third conductor portion is equal to a distance between the fourth magnetoelectric conversion element and the third conductor portion in plan view.

20. The current sensor according to claim 19, wherein the first magnetoelectric conversion element, the second magnetoelectric conversion element, the third magnetoelectric conversion element, and the fourth magnetoelectric conversion element are built in a chip configuring the signal processing IC.

21. The current sensor according to claim 17, further comprising:
a third magnetoelectric conversion element arranged in the circuit surface of the signal processing IC while facing the first magnetoelectric conversion element across the second conductor portion in plan view; and
a fourth magnetoelectric conversion element arranged in the circuit surface of the signal processing IC while facing the second magnetoelectric conversion element across the fourth conductor portion in plan view, wherein
the first magnetoelectric conversion element is positioned in a region surround by the first current conductor in plan view,
the second magnetoelectric conversion element is positioned in a region surround by the second current conductor in plan view,
a distance between the first magnetoelectric conversion element and the sixth conductor portion is equal to a distance between the third magnetoelectric conversion element and the sixth conductor portion in plan view,
a distance between the second magnetoelectric conversion element and the third conductor portion is equal to a distance between the fourth magnetoelectric conversion element and the third conductor portion in plan view, and
the first magnetoelectric conversion element, the second magnetoelectric conversion element, the third magnetoelectric conversion element, and the fourth magnetoelectric conversion element have a sensitivity axis in a third direction that intersects with the first direction and the second direction.

22. The current sensor according to claim 21, wherein the first magnetoelectric conversion element, the second magnetoelectric conversion element, the third magnetoelectric conversion element, and the fourth magnetoelectric conversion element are built in a chip configuring the signal processing IC.

23. The current sensor according to claim 21, wherein
the first magnetoelectric conversion element is positioned on an extending line on which the fourth conductor portion extends in plan view,
the third magnetoelectric conversion element is positioned on an extending line on which the fifth conductor portion extends in plan view,
the second magnetoelectric conversion element is positioned on an extending line on which the second conductor portion extends in plan view, and
the fourth magnetoelectric conversion element is positioned on an extending line on which the first conductor portion extends in plan view.

24. The current sensor according to claim 23, wherein
the first magnetoelectric conversion element is positioned on a perpendicular bisector of a line segment which connects the second magnetoelectric conversion element and the fourth magnetoelectric conversion element in plan view, and
the second magnetoelectric conversion element is positioned on a perpendicular bisector of a line segment which connects the first magnetoelectric conversion element and the third magnetoelectric conversion element in plan view.

25. The current sensor according to claim 21, wherein the first magnetoelectric conversion element, the second magnetoelectric conversion element, the third magnetoelectric conversion element, and the fourth magnetoelectric conversion element are each a Hall element which has a sensitivity axis in a direction that intersects with a magnetically sensitive surface and uses a Hall effect.

26. The current sensor according to claim 17, wherein
the first current conductor and the second current conductor have a same shape,
the first current conductor and the second current conductor are arranged in a 180-degree rotated positional relationship in plan view,
the current sensor further comprises
a third magnetoelectric conversion element arranged facing the first magnetoelectric conversion element in the second direction, and
a fourth magnetoelectric conversion element arranged facing the second magnetoelectric conversion element in the second direction,
an entire magnetically sensitive surface of the first magnetoelectric conversion element overlaps with the first conductor portion in plan view,
an entire magnetically sensitive surface of the third magnetoelectric conversion element overlaps with the second conductor portion in plan view,
an entire magnetically sensitive surface of the second magnetoelectric conversion element overlaps with the fourth conductor portion in plan view,
an entire magnetically sensitive surface of the fourth magnetoelectric conversion element overlaps with the fifth conductor portion in plan view, and
the first magnetoelectric conversion element, the second magnetoelectric conversion element, the third magnetoelectric conversion element, and the fourth magnetoelectric conversion element have a sensitivity axis in the second direction.

27. The current sensor according to claim 26, wherein
the first magnetoelectric conversion element, the second magnetoelectric conversion element, the third magnetoelectric conversion element, and the fourth magnetoelectric conversion element are built in a chip configuring the signal processing IC.

28. A current sensor module comprising:
the current sensor according to claim 5; and
a substrate to which the current sensor is mounted, wherein
the substrate has a first slit and a second slit which extend in a second direction that intersects with the first direction,
in plan view, an exposed portion of the signal conductor from the sealing section exists between the first slit and the second slit, and also the first slit exists between an exposed portion of the first current conductor from the sealing section and an exposed portion of the signal conductor from the sealing section, and the second slit exists between an exposed portion of the second current conductor from the sealing section and an exposed portion of the signal conductor from the sealing section, and
the first slit and the second slit extend on an outer side relative to the third surface and the fourth surface of the sealing section in plan view.

29. The current sensor module according to claim 28, wherein
the current sensor further includes a second groove formed along the second surface or the third surface, and
the first slit and the second slit are arranged in at least positions which face portions of the first groove and the second groove of the sealing section along the second direction facing the substrate.

30. A current sensor module comprising:
the current sensor according to claim 9; and
a substrate to which the current sensor is mounted, wherein
the substrate includes a first slit which extends in the first direction and a second slit which extends in a second direction that intersects with the first direction,
the first slit exists between an exposed portion of the first current conductor from the sealing section and an exposed portion of the second current conductor from the sealing section and an exposed portion of the signal conductor from the sealing section and extends on an outer side relative to the first surface and the second surface of the sealing section in plan view, and
the second slit exists between an exposed portion of the first current conductor from the sealing section and an exposed portion of the second current conductor from the sealing section and extends on an outer side relative to the fourth surface of the sealing section in plan view.

31. The current sensor module according to claim 30, wherein
the first slit is arranged in at least a position facing a portion of the first groove and the second groove of the sealing section, the portion facing the substrate and being along the first direction,
the second slit is arranged in at least a position facing a portion of the fifth groove of the sealing section, the portion facing the substrate and being along the second direction, and
the first slit and the second slit communicate.
